(19) United States
(12) Patent Application Publication
(10) Pub. No.: US 2026/0338856 A1
(43) Pub. Date: Oct. 29, 2026

(54) TRANSPORTING MEDIA FOR INSPECTION WITH LOW PARTICLE GENERATION

(71) Applicant: Applied Materials, Inc., Santa Clara, CA (US)

(72) Inventors: Paul FORDERHASE, Austin, TX (US); James D. STRASSNER, Austin, TX (US); Mario Daniel SANCHEZ, San Jacinto, CA (US); Kazuya DAITO, Milpitas, CA (US)

(21) Appl. No.: 19/119,729

(22) PCT Filed: Oct. 27, 2023
(86) PCT No.: PCT/US2023/036090

§ 371 Date: Apr. 9, 2025

(51) Int. Cl. G01R 31/28; G01N 35/04

(52) U.S. Cl. CPC G01R 31/2893; G01N 35/04; G01R 31/2862; G01R 31/2867; G01N 2035/0424; G01N 2035/0439; G01N 2035/0475; G01N 2035/0484; G01N 2035/0487

(57) ABSTRACT

The present disclosure relates to a system for inspecting devices, such as semiconductor devices, or units under test (UUTs). The system may include a transport media transport system that adjusts to accept transport media of different sizes, resulting in a universal design that can manipulate a wide variety of transport media that formerly required manual manipulation or multiple inspection systems. The system may include an inspection system to inspect the UUTs and a positioning system to move the transport media from a dispenser to the inspection system. The system may include a transport media alignment system to orient and align the transport media and UUTs to the inspection system. The system described herein may lead to faster and more precise UUT placement, improving the inspection process and quality of the end product alike.

### BACKGROUND

### Field

Embodiments of the present disclosure generally relate to apparatuses and methods of inspecting units under test (UUTs), e.g., semiconductor devices. More specifically, embodiments described herein relate to orienting and aligning transport media and UUTs for inspection by metrology systems.

### Description of the Related Art

Various systems, such as metrology systems, may be used to inspect different types of units under test (UUTs) on transport media. Types of UUTs may include semiconductor devices, e.g., whole wafers prior to dicing provided on wafer carriers and/or diced wafers provided on matrix trays. Conventional systems for inspecting UUTs have limited capability, if any, to orient or align UUTs prior to inspection. Improperly aligned UUTs may result in inaccurate inspection results. For example, measurements taken by the metrology systems may not be aligned to a same reference frame as a reference standard to which they are compared. To compensate, tighter tolerances may be used to manufacture the transport media (e.g., matrix transport trays or wafer carriers) to achieve correct angular orientation during inspection. The tighter toleranced transport media may result in increased manufacturing cost and difficulty. The issue of aligning the frames of reference is compounded for certain transport media types, such as matrix trays, which contain several UUTs to be inspected as each UUT on the matrix tray may have a different reference frame than the other UUTs. Conventional inspection systems may not be able to align a frame of reference for each UUT of the tray.

Conventional systems for inspecting UUTs may not be able to account for transport media of differing shapes, geometries, and sizes. As a result, different systems may be used to inspect each of, for example, a 150 mm wafer, a 200 mm wafer, and a matrix tray. Using different inspection systems may increase a cost to inspect UUTs and require more maintenance than a single inspection system.

Therefore, there is a need for a system and a method of orienting and aligning transport media and UUTs for inspection that solves the problems described above.

### SUMMARY

The present disclosure relates to a system for inspecting devices, such as semiconductor devices, or units under test (UUTs). The system may include a transport media transport system that adjusts to accept transport media of different sizes, resulting in a universal design that can manipulate a wide variety of transport media that formerly required manual manipulation or multiple inspection systems. The system may include an inspection system to inspect the UUTs and a positioning system to move the transport media from a dispenser to the inspection system. The system may include a transport media alignment system to orient and align the transport media and UUTs to the inspection system. The system described herein may lead to faster and more precise UUT placement, improving the inspection process and quality of the end product alike.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIGS. 1A and 1B depict a trimetric view of a system for inspecting units under test (UUTs), according to some embodiments.

FIG. 2A depicts a trimetric view of an adjustment system, according to some embodiments.

FIG. 2B depicts a cross-sectional view of the adjustment system from FIG. 2A, according to some embodiments.

FIG. 2C depicts a cross-sectional view of the adjustment system from FIG. 2A, according to some embodiments.

FIG. 2D depicts a trimetric view of the adjustment system from FIG. 2A with a different UUT type, according to some embodiments.

FIG. 3A depicts a trimetric view of a UUT alignment system, according to some embodiments.

FIG. 3B depicts a trimetric view of a positioning plate of an adjustment system, according to some embodiments.

FIG. 3C depicts a trimetric view of a mounting plate of an adjustment system, according to some embodiments.

FIGS. 3D and 3E depict a top view of a UUT alignment system, according to some embodiments.

FIGS. 3F and 3G depict front and left side views, respectively, of a UUT alignment system, according to some embodiments.

FIGS. 3H and 3I depict front and left side views, respectively, of a UUT alignment system, according to some embodiments.

FIGS. 3J and 3K depict front and right side views, respectively, of a UUT alignment system, according to some embodiments.

FIG. 4 depicts a trimetric view of an adjustment system, according to some embodiments.

FIGS. 5A, 5B, and 5C depict flowcharts of methods of inspecting UUTs, according to some embodiments.

FIGS. 6A and 6B depict a top view of an adjustment system grasping UUTs, according to some embodiments.

FIGS. 6C, 6D, 6E, 6F, 6G, and 6H depict different views of UUTs being inspected by a system for inspecting UUTs, according to some embodiments.

FIG. 7A depicts a trimetric view of vacuum housings on an adjustment system, according to some embodiments.

FIG. 7B depicts a cross-sectional top view of a vacuum housing of the adjustment system from FIG. 7A, according to some embodiments.

FIG. 7C depicts a cross-sectional top view of a vacuum housing of the adjustment system from FIG. 7A, according to some embodiments.

FIG. 8 depicts a schematic view of an example system controller that can be used according to the systems and methods described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the present disclosure. However, it will be apparent to one of skill in the art that some embodiments of the present disclosure may be practiced without one or more of these specific details. In other instances, well-known features have not been described in order to avoid obscuring one or more embodiments of the present disclosure.

Aspects of the present disclosure provide a system and methods for orienting and aligning transport media and units under test (UUTs) for inspection.

The embodiments of the system for inspecting UUTs described herein address the issues discussed above. The system may include a media transport system that adjusts to accept transport media of different sizes, resulting in a universal design that can manipulate a wide variety of transport media that formerly required manual manipulation or multiple inspection systems. The system may include an inspection system to inspect the UUTs on the transport media and a positioning system to move the transport media from a dispenser to the inspection system. The system may include a transport media alignment system to orient and align the UUTs to the inspection system. The system described herein may lead to faster and more precise UUT placement, improving the inspection process and quality of the end product alike.

### Examples of Systems for Inspecting Units Under Test (UUTs)

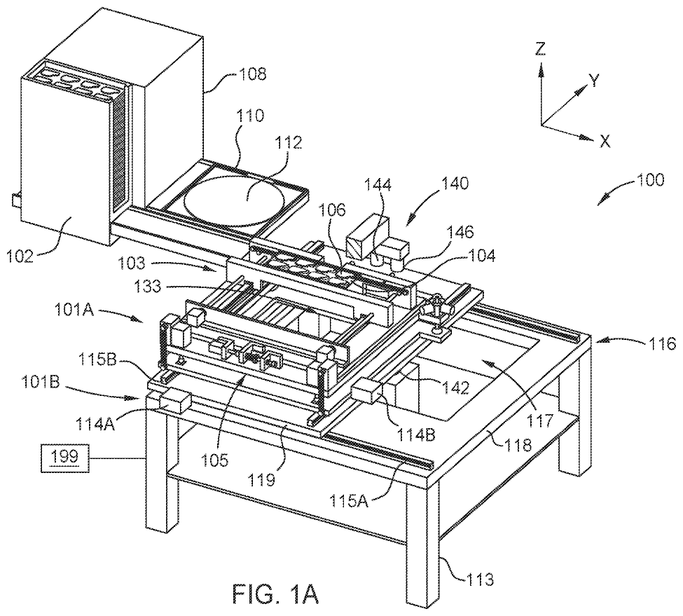

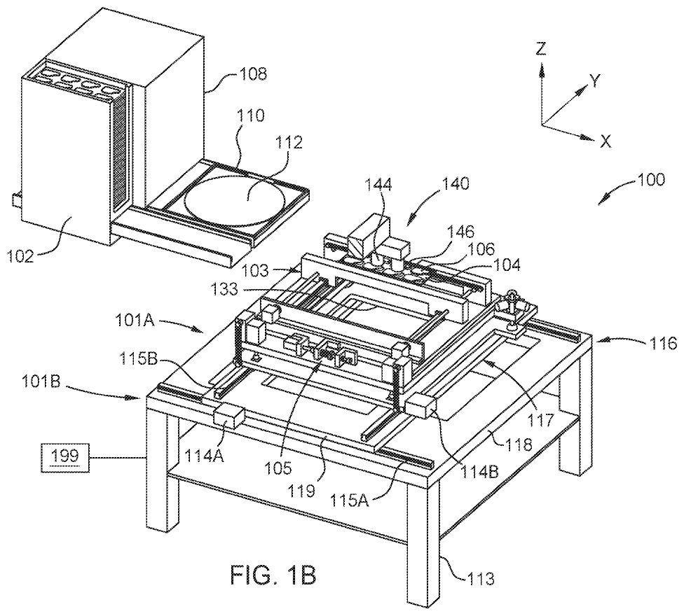

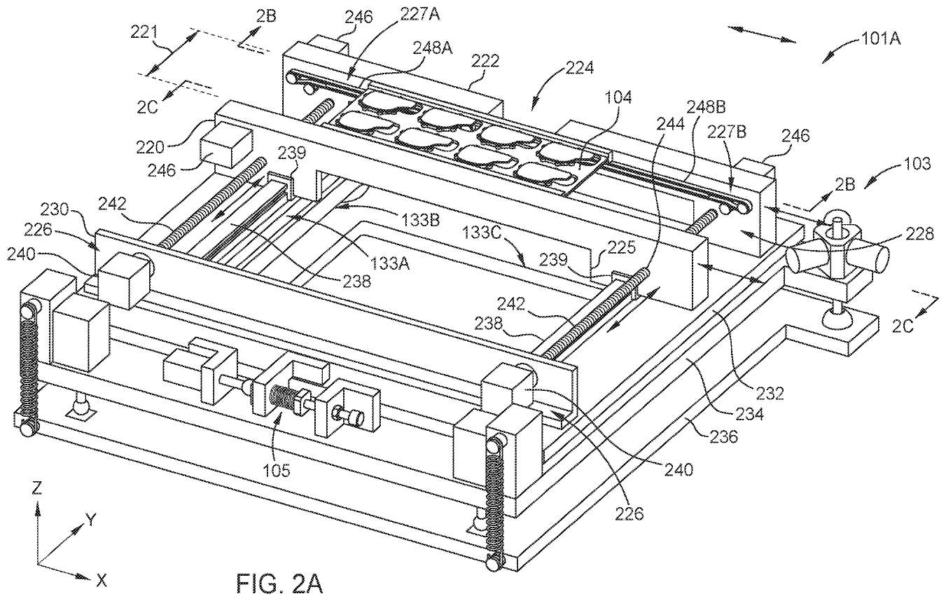

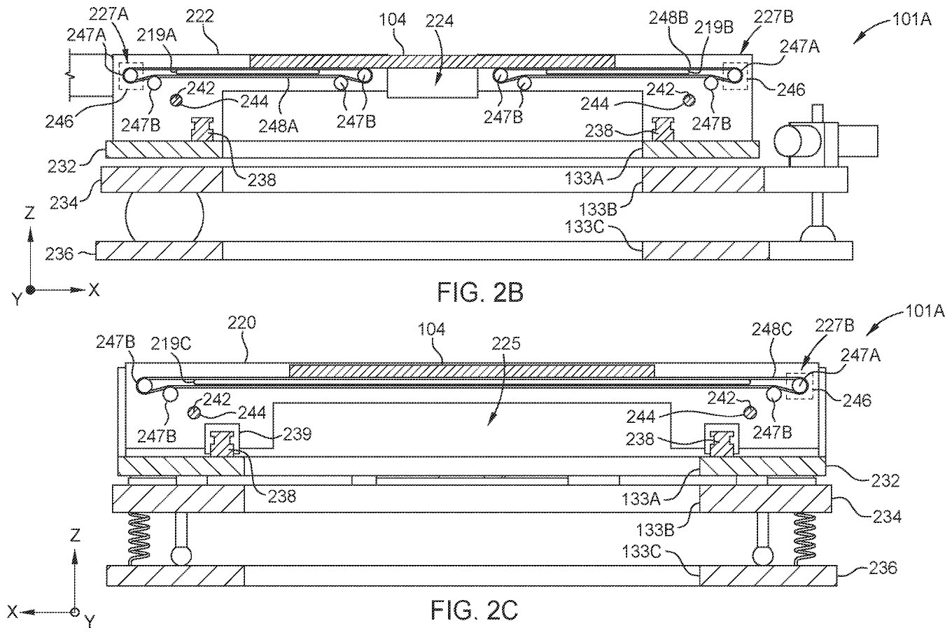

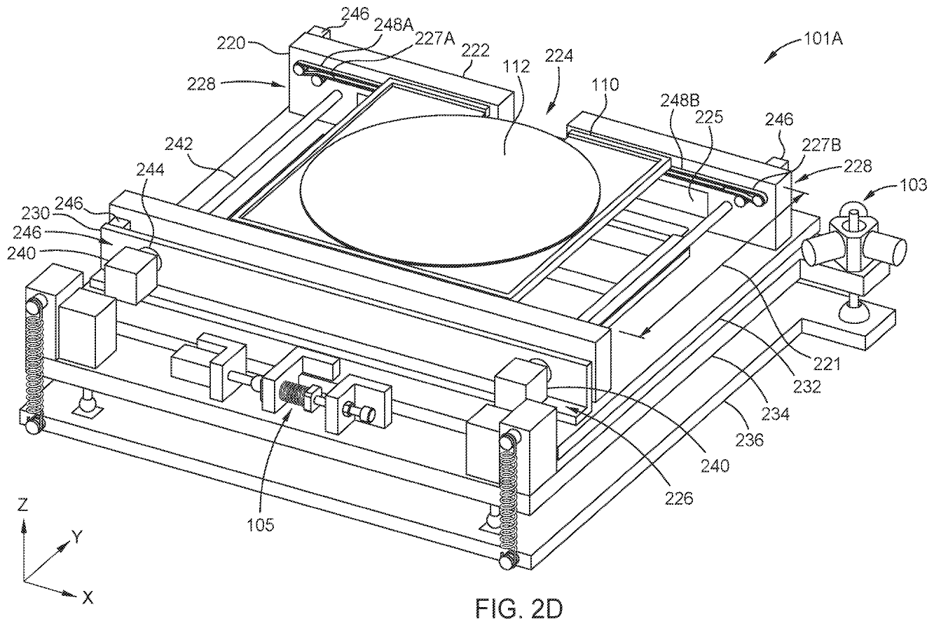

FIGS. 1A and 1B depict a trimetric view of a system for inspecting UUTs 100, according to some embodiments. In particular, FIG. 1A shows the system for inspecting UUTs 100 (referred to as the system 100 or a UUT inspection system) accepting transport media from a dispenser. In the embodiments depicted in FIGS. 1A and 1B, the dispenser is a matrix tray dispenser 102. The matrix tray dispenser 102 feeds matrix trays 104 to the system 100. The dispenser may also be a substrate tray dispenser 108 that dispenses substrate trays 110 containing substrates 112 to the system 100, such as discussed in relation to FIG. 2E. The matrix trays 104 and substrate trays 110 are examples of different transport media types. A coordinate system is shown to facilitate discussion in relation to a location and orientation of components of the system 100 for inspecting UUTs (referred to as the system 100), but is not meant to define a specific origin.

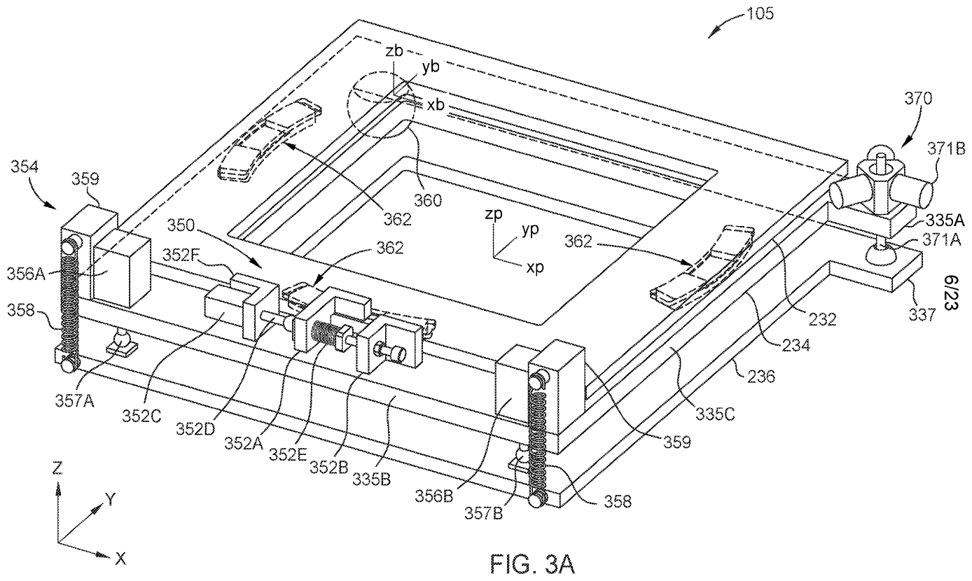

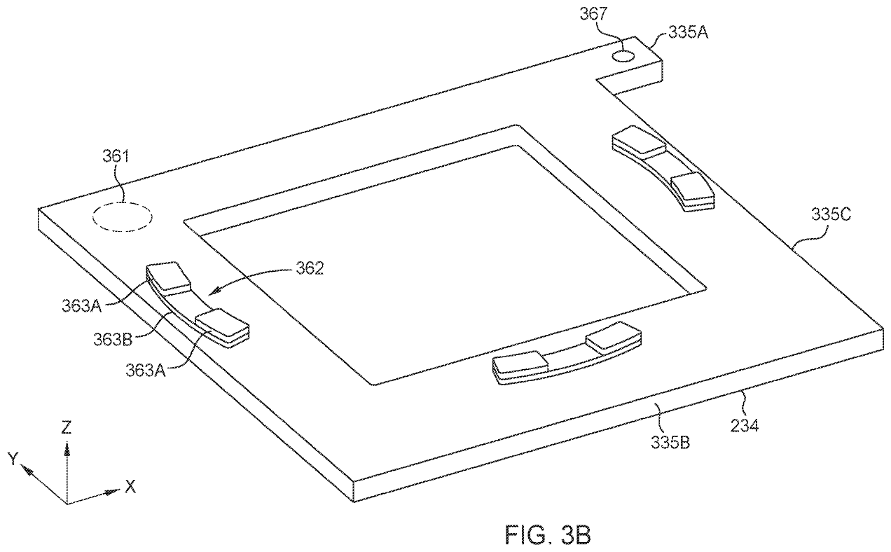

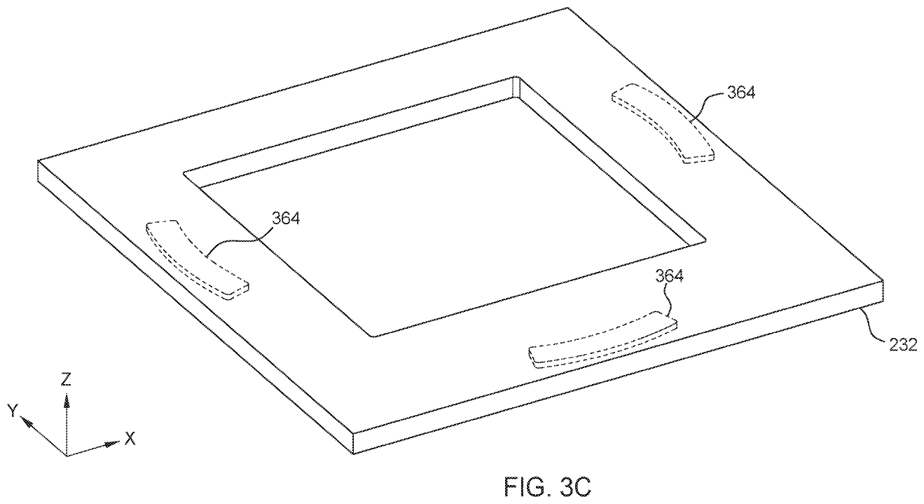

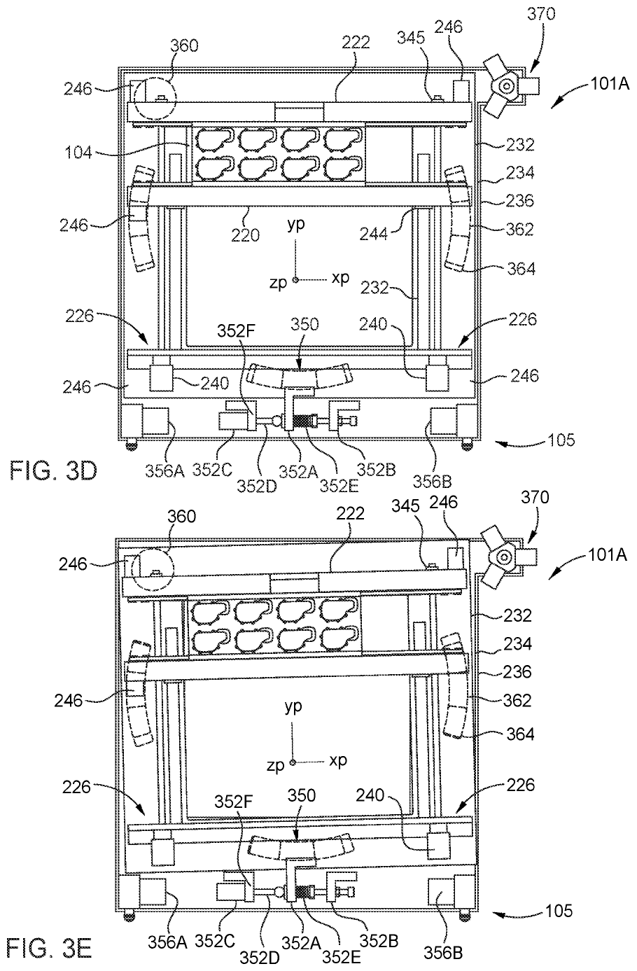

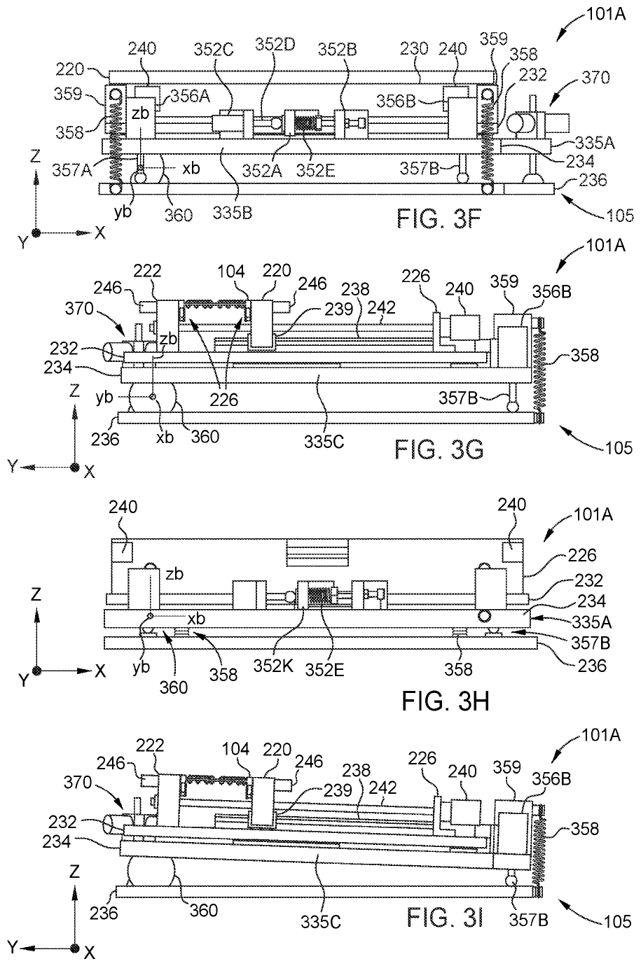

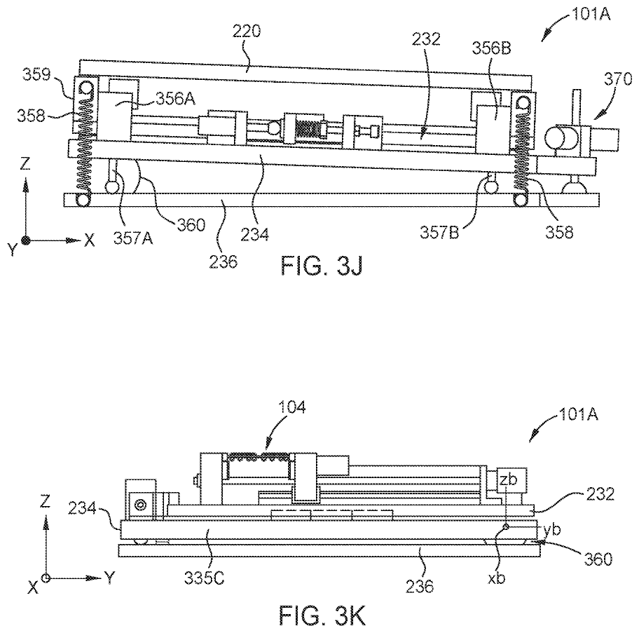

As shown in FIG. 1A, the system 100 includes an adjustment system 101A, a positioning system 101B, an inspection system 140, and a system controller 199. The adjustment system 101A includes a transport media transport system 103 and a UUT alignment system 105. The transport media transport system 103 forms an opening 133 in a central portion of the adjustment system 101A. Transport media, such as a matrix tray 104, is disposed on the adjustment system 101A. The adjustment system 101A moves and rotates the matrix tray 104 to align the matrix tray 104 to the coordinate system (or any desired coordinate system, such as a coordinate system of the inspection system 140) for inspection by the inspection system 140. The transport media transport system 103 is further discussed in relation to FIGS. 2A-2E. The UUT alignment system 105 is further discussed in relation to FIGS. 3A-3K.

The positioning system 101B moves the adjustment system 101A about a plane, such as a plane formed by an x- and y-axis of the coordinate system. The positioning system 101B includes positioning actuators 114 (e.g., a first positioning actuator 114A and a second positioning actuator 114B), positioning tracks 115 (e.g., a first pair of positioning tracks 115A and a second pair of positioning tracks 115B), and a positioning structure 116.

The positioning structure 116 includes a fixed plate 118 coupled to positioning legs 113 and a movable plate 119. The positioning legs 113 may be coupled to a floor, platform, or other equipment. The first pair of positioning tracks 115A are coupled to the fixed plate 118. The second pair of positioning tracks 115B are coupled to the movable plate 119 and are positioned substantially perpendicular (or orthogonal) on an x-y plane to the first pair of positioning tracks 115A, such as 90 degrees within +/−5 degrees, such as 90 degrees within +/−2 degrees, such as 90 degrees within +/−1 degree, such as 90 degrees within +/−0.5 degrees, such as 90 degrees within +/−0.25 degrees. The tracks 115A and 115B may be coupled to the plates 118 and 119 through fasteners, a weld, an adhesive, and the like. Fasteners may include any one of bolts and nuts, screws, anchors, rivets, and the like.

The first positioning actuator 114A moves the movable plate 119 along the first pair of positioning tracks 115A. The second positioning actuator 114B moves the adjustment system 101A along the second pair of positioning tracks 115B. In the embodiment depicted in FIG. 1A, the first positioning actuator 114A is coupled to the movable plate 119 and the second positioning actuator 114B is coupled to the adjustment system 101A. The positioning actuators 114A and 114B are used to move the adjustment system 101A along the x and y-axes, which beneficially allow the system 100 to receive transport media from different dispensers (e.g., the dispensers 102 and 108). For example, the second positioning actuator 114B may move the adjustment system 101A along the y-axis to receive the substrate tray 110. The positioning actuators 114A and 114B move the adjustment system 101A in relation to the fixed plate 118. The fixed plate 118 and the movable plate 119 each form an opening 117 in a central portion.

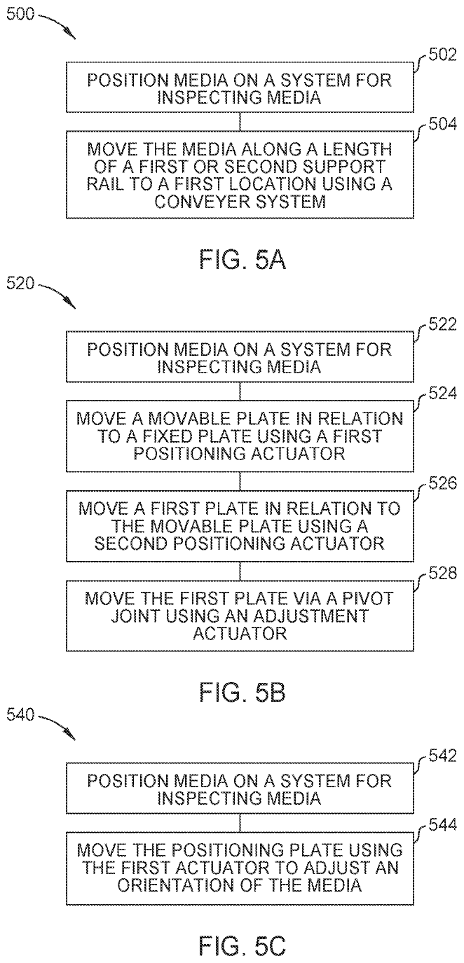

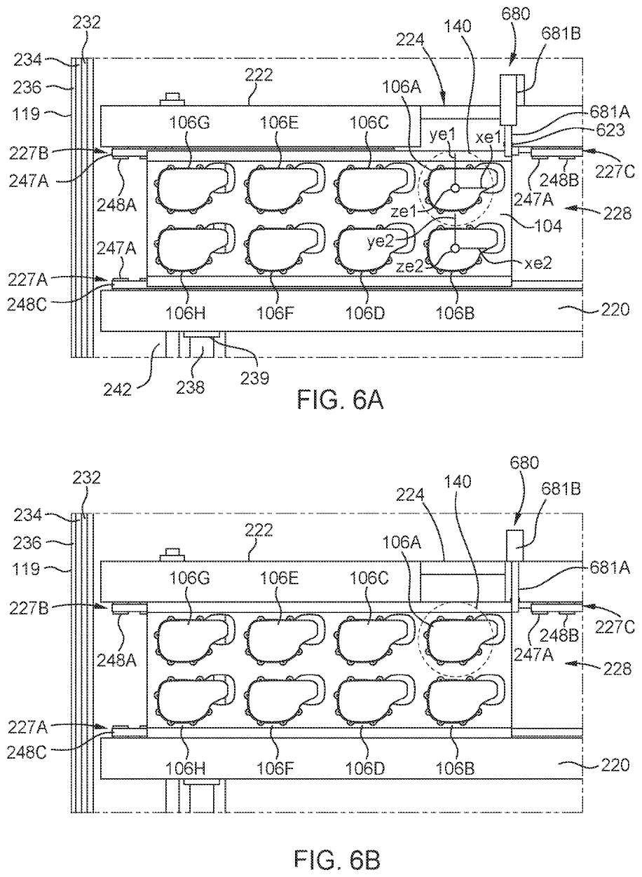

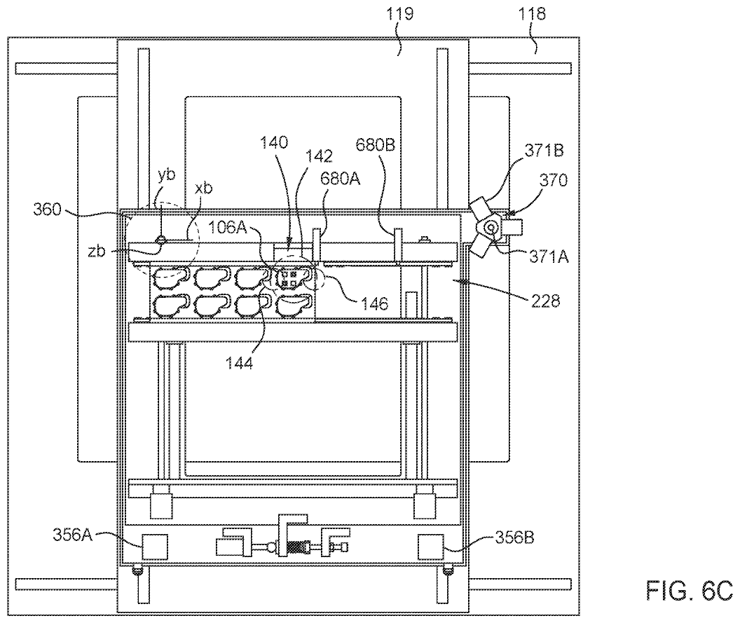

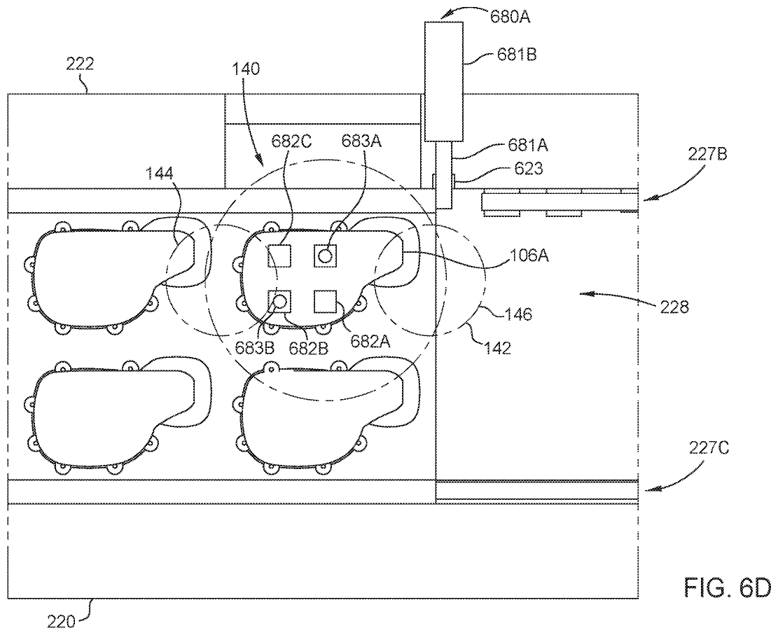

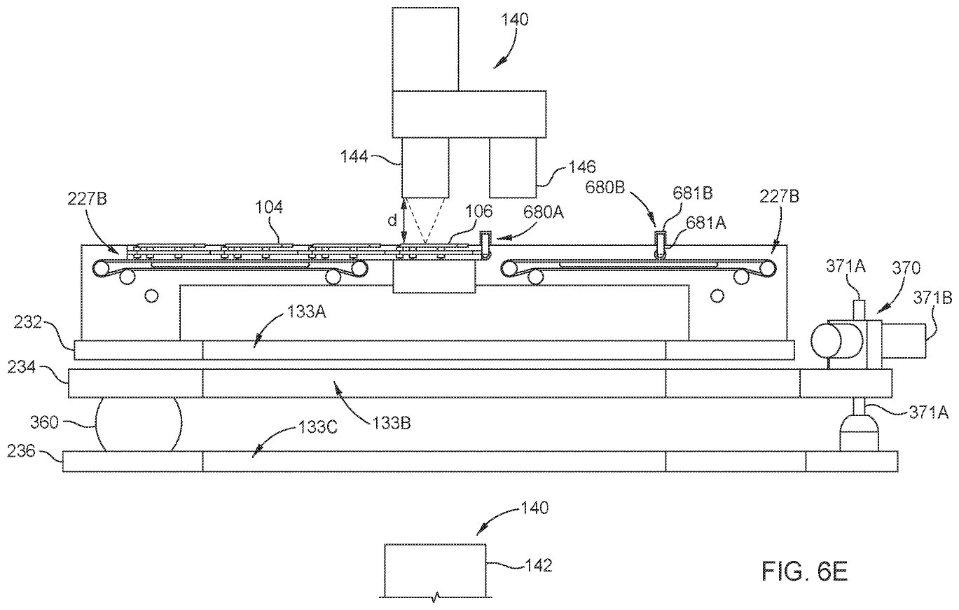

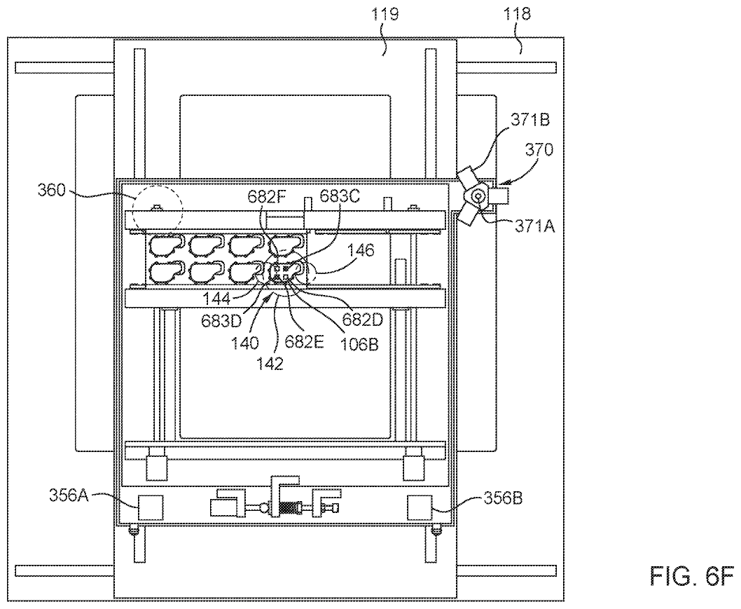

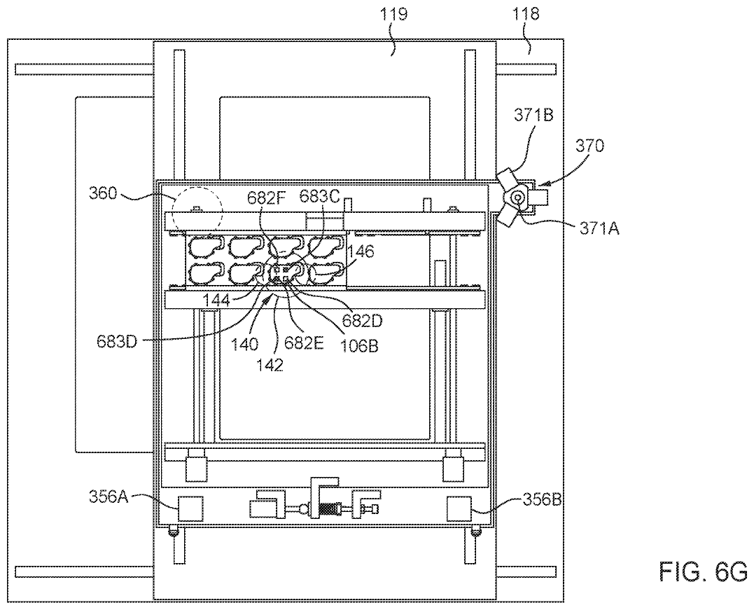

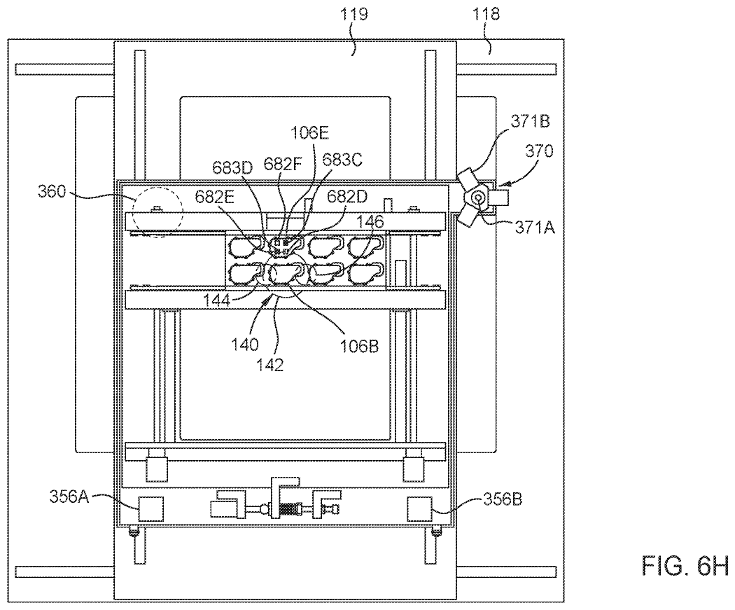

The inspection system 140 includes an inspection device 142, a distance sensor 144, and an imaging system 146. The distance sensor 144 and imaging system 146 are positioned above the inspection device 142, such as when viewed from the side as in FIG. 6E. Stated differently, the distance sensor 144 and imaging system 146 are a distance away from the inspection device along the z-axis. The distance sensor 144 and imaging system 146 are used as inputs to the system controller 199 to control the system 100 to position and align the transport media (e.g., the matrix tray 104), such as discussed in relation to FIGS. 5A-6H and 8.

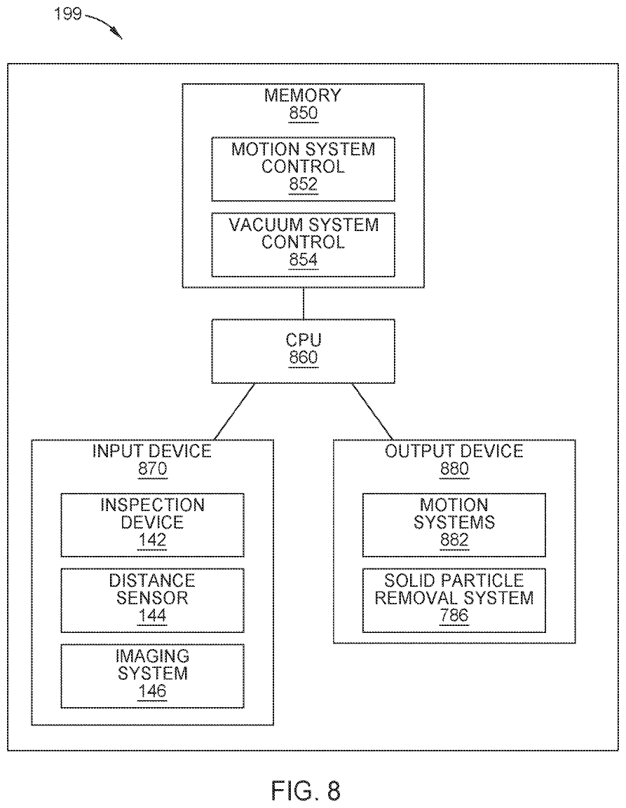

The system controller 199 is used to control the system 100. The system controller 199 moves the adjustment system 101A by controlling the positioning actuators 114A and 114B. In some embodiments, the first and second positioning actuators 114A and 114B move the transport media and the UUTs to and from the inspection system 140. The system controller 199 may also be used to control the inspection system 140, or to use the inspection system 140 as an input to control the positioning actuators 114A and 114B. The system controller 199 is further discussed in relation to FIG. 8.

FIG. 1B shows the adjustment system 101A at a position for inspecting the matrix tray 104. The positioning actuators 114A and 114B have moved the adjustment system 101A along the x and y-axes such that the opening 133 at least partially overlaps the opening 117 when viewed from above. Partially aligning the openings 133 and 117 allows the inspection system 140 to have a line-of-sight to the UUTs (e.g., on the matrix tray 104). For example, a portion of the matrix tray 104 with UUTs to be inspected is positioned over the inspection device 142 and the distance sensor 144 and imaging system 146 are positioned above the matrix tray 104. In some embodiments, the opening 133 is entirely disposed over the opening 117 at the position for inspecting the matrix tray 104 when viewed from above.

The positioning system 101B may position the adjustment system 101A prior to inspection. In some embodiments, the positioning system 101B moves the adjustment system 101A to a general desired area and the transport media transport system 103 moves the media to a desired location. The adjustment system 101A may position the matrix tray 104 to a higher degree of accuracy than the positioning system 101B. In some embodiments, the positioning system 101B may be used to move the matrix tray 104 to the desired location. In such embodiments, the adjustment system 101A may be used to make fine adjustments.

In some embodiments, the positioning actuators 114 may also include a third actuator (not shown) to move the system 100 along a z-axis. In some embodiments, at least one of the positioning actuators 114 may rotate the system 100 about the x, y, and z-axes instead of or in addition to moving the system 100 along the axes. In some embodiments, a single positioning actuator 114 is used. In some embodiments, only the second positioning actuator 114B is used to move the adjustment system 101A along the y-axis, as discussed in relation to FIG. 6F.

In the embodiment depicted in FIGS. 1A and 1B, the matrix tray 104 contains eyepieces 106. In such embodiments, the system 100 may use the inspection system 140 to inspect each eyepiece 106 of the matrix tray 104, such as discussed in relation to FIGS. 5A-6H.

In some embodiments, the matrix trays 104 are used for handling, transport, and storage of integrated circuits (ICs), modules, and other components. In some embodiments, the matrix trays 104 conform to Joint Electron Device Engineering Council (JEDEC) standards, and may be referred to as JEDEC trays.

In some embodiments, the positioning actuators 114A and 114B may be coupled to other parts of the system 100 (e.g., the fixed plate 118). The fixed plate 118 remains stationary in relation to the movable plate 119. In some embodiments, the fixed plate 118 moves the adjustment system 101A using the positional actuators 114A and 114B without the movable plate 119. In some embodiments, the positioning system 101B operates similar to a gantry system or a motion system of a computer numerical control (CNC) router to move the adjustment system 101A.

Although dispensers 102 and 108 are discussed, dispensers for other transport media and UUTs that may be inspected by the system 100 are contemplated. In some embodiments, a person or robot may place the transport media and UUTs in the system.

### Examples of Adjustment Systems

FIG. 2A depicts a trimetric view of the adjustment system 101A, according to some embodiments. In particular, FIG. 2A shows the matrix tray 104 disposed on the adjustment system 101A.

The adjustment system 101A includes a first support rail 220, a second support rail 222, a first motion system 226, a second motion system 228, a mounting rail 230, a mounting plate 232, a positioning plate 234, and a base plate 236.

The first motion system 226 includes rail actuators 240 that move the first support rail 220 toward and away from the second support rail 222 (e.g., along the y-axis) and allows the adjustment system 101A to be adjusted to receive transport media and UUTs of different sizes. For example, the first motion system 226 adjusts a position of the first support rail 220 such that a gap 221 is formed and sized to accommodate the matrix tray 104 (e.g., slightly larger than a width of the matrix tray 104).

The rail actuators 240 are coupled to the mounting rail 230, which is coupled to the mounting plate 232. The second support rail 222 is also fixed to the mounting plate 232 at an opposite end than the mounting rail 230. Each rail actuator 240 of the rail actuators 240 is coupled to a shaft 242. Each shaft 242 includes a threaded portion to engage one of a plurality of threaded holes 244 formed in the first support rail 220 or a threaded insert (not shown) disposed in the first support rail 220. Each rail actuator 240 rotates its respective shaft 242 about an axis and the threaded portion of the shaft 242 engages the respective threaded hole 244 to pull or push the first support rail 220 towards or away from the mounting rail 230. Each shaft 242 travels through one of a plurality of through-holes in the second support rail 222 and is secured using a retaining ring (e.g., a retaining ring 345 in FIG. 3B), a clip, or lock nut or other fasteners. Thus, each shaft 242 is fixed from translating and is constrained to rotate in-place. The rotational motion of each shaft 242 translates into linear motion of the first support rail 220. The linear motion of the first support rail 220 results in increasing or decreasing an axial distance of gap 221 (e.g., distance along y-axis) such that the distance between the first support rail 220 and the second support rail 222 is adjusted to accommodate a change in transport media (e.g., from JEDEC trays to substrate carriers).

The first motion system 226 further includes guides 239 coupled to the first support rail 220 to guide movement of the first support rail 220. The guides 239 are slidably coupled to tracks 238 and allow the first motion system 226 to move the first support rail 220 along the tracks 238. The guides 239 include a corresponding feature to mate with the tracks 238. For example, the guides 239 may include a protrusion to engage and slide along a channel in the tracks 238. In some embodiments, the guides 239 may be a c-channel, u-channel, or strut channel and the tracks 238 may be a square tube or square beam. In such embodiments, an inner surface of the channel engages an outer surface of the tube or beam.

The guides 239 may be coupled to the first support rail 220 through fasteners (e.g., a set screw and the like). In some embodiments, the guides 239 are integrally formed with the first support rail 220. For example, the guides 239 may be machined out of, welded to, bonded to, or otherwise joined to the first support rail 220 to function as a single article.

In some embodiments, the tracks 238, the guides 239, or both may include a non-stick or low-friction material, such as a ultra-high molecular weight polyethylene, high density polyethylene, ceramic, polytetrafluoroethylene, silicone non-stick, or enamel, to allow the first support rail 220 to move in relation to the tracks 238. In some embodiments, the non-stick or low-friction material is applied as a coating. In some embodiments, the guides 239 may be recirculating ball bearing linear guides. In some embodiments, the non-stick or low-friction material is applied as a tape. In some embodiments, the tracks 238 or the guides 239 may wear over time and may be replaced.

The first motion system 226 may be used to grasp the matrix tray 104 with the support rails 220 and 222, such as discussed in relation to FIG. 6B. For example, the matrix tray 104 may be grasped between inner sides of the support rails 220 and 222 that face one another. In the depicted embodiment, the second support rail 222 forms a gap 224 to provide clearance for an end effector of a robot (not shown). The robot may be used to position UUTs on the matrix tray 104 such as by an Equipment Front End Module (EFEM) where the EFEM is used to transport the UUTs to the system 100. The gap 224 may provide additional clearance (e.g., along the z-axis) for other equipment, such as inspection optics or illumination sources, to clear the second support rail 222 from above the second support rail 222. For example, the gap 224 may provide clearance for the distance sensor 144 or the imaging system 146 when the positioning system 101B moves the adjustment system 101A (as discussed in relation to FIGS. 1A and 1B) for inspection of the matrix tray 104.

The second motion system 228 is coupled to the support rails 220 and 222 and is configured to displace the matrix tray 104 in an axial direction (e.g., along the x-axis) after the second motion system 228 receives the matrix tray 104 from the matrix tray dispenser 102. In the embodiment depicted in FIG. 2A, the second motion system 228 includes conveyer systems 227A, 227B which are further discussed in relation to FIGS. 2B and 2C. Each conveyer system 227A, 227B includes belt actuators 246 and a belt 248A, 248B. The matrix tray 104 may be disposed on the belt 248A, 248B. For example, the belt 248A, 248B may support outer portions or edges of the matrix tray 104. The belt actuators 246 move the belt 248A, 248B and matrix tray 104 toward and away from the matrix tray dispenser 102 (e.g., along the x-axis). All belt movement in the system 101A, including the movement of belt 248A, 248B, should be simultaneous to allow uniform displacement of the matrix tray 104. Such simultaneous movement may be achieved by synchronizing all belt motors or, alternatively, by a single drive shaft connecting coaxial belt actuators 246. The second motion system 228 may move or pull the matrix tray 104 in between the support rails 220 and 222 and adjust a position of the matrix tray 104 (e.g., along the x-axis). The second motion system 228 may be used to present the matrix tray 104 to the inspection system 140 for inspection.

The mounting plate 232 is rotatably coupled to the positioning plate 234 and the positioning plate 234 is rotatably coupled to the base plate 236, such as discussed in relation to FIGS. 3A-3I. The mounting plate 232 forms an opening 133A, the positioning plate 234 forms an opening 133B, and the base plate 236 forms an opening 133C. The openings 133A, 133B, and 133C collectively form the opening 133 (FIG. 1A) of the adjustment system 101A.

The mounting rail 230, second support rail 222, and tracks 238 are coupled to the mounting plate 232 through fasteners (e.g., any one of bolts and nuts, screws, anchors, rivets, or a combination thereof), welds, adhesives, or combinations thereof. The rail actuators 240 may be similarly coupled to the mounting rail 230.

In some embodiments, the rail actuators 240 may be coupled to the second support rail 222. In such embodiments, the first motion system 226 may not include the mounting rail 230.

Although the first motion system 226 is shown with two rail actuators 240, some embodiments may only use one rail actuator 240. For example, the one rail actuator 240 may move the first support rail 220 using a first shaft 242 (e.g., one of the shafts 242 in FIG. 2A). A second shaft 242 (e.g., the other shaft 242 in FIG. 2A), which does not have a threaded portion and is not coupled to a rail actuator 240, is used to guide the first support rail 220 as it moves.

FIG. 2B is a cross-sectional view taken across line 2B-2B of the adjustment system 101A from FIG. 2A, according to some embodiments. As shown in FIG. 2B, the second support rail 222 includes two conveyer systems, first conveyer system 227A and second conveyer system 227B, coupled to the second support rail 222. An outer portion or edge of the matrix tray 104 rests on the conveyer systems 227A and 227B. The first and second conveyer systems 227A and 227B are positioned on each side (e.g., a left and right side as shown on the page) of the gap 224, and are mirrored versions of one another.

The first conveyer system 227A includes a motorized pulley 247A or motorized wheel coupled to the belt actuator 246. The belt actuator 246 rotates the motorized pulley 247A about an axis. The first conveyer system 227A further includes the belt 248A that forms a loop around and travels around the motorized pulley 247A and free-spinning pulleys 247B or wheels (e.g., idler pulleys). The pulleys 247B provide tension and guide the belt 248A around a belt guard 219A of the second support rail 222. The belt guard 219A is configured to contain dust that may be generated by the belt 248A. In some embodiments, the belt 248A is flat, rests in a channel or groove of the motorized pulley 247A, and moves through tension and friction between the belt 248A and the motorized pulley 247A. The pulleys 247B may be positioned on a lower side of and on a left and right side of belt guard 219A (as shown on the page). A bearing may be used to assist the motorized pulley 247A or the pulleys 247B rotate. In some embodiments, the belt 248A is a flat belt and the motorized pulley 247A and free-spinning pulleys 247B are crowned pulleys. Having the motorized pulley 147A and free-spinning pulleys 247B be crowned pulleys controls the position of the belt along the axis of the pulleys. This arrangement allows the edges of the belts to be away from stationary components of the adjustment system 101A and reduces dust or particle generation by the belts.

In some embodiments, the belt guard 219A or an inner surface of the second support rail 222 (e.g., a surface that faces the first support rail 220) may include a non-stick or low-friction material, such as discussed in relation to the tracks 238 in FIG. 2A, to allow the belt 248A to move in relation to the belt guard 219A and the second support rail 222.

The conveyer system 227B is similarly configured and includes a motorized pulley 247A, a belt 248B, pulleys 247B, and a belt guard 219B.

FIG. 2C depicts a cross-sectional view taken across line 2C-2C of the adjustment system 101A from FIG. 2A, according to some embodiments. In particular, FIG. 2C shows a third conveyer system 227C of the second motion system 228.

The first support rail 220 includes the conveyer system 227C on which an outer portion or edge of the matrix tray 104 rests. The outer portion is on an opposite side of the matrix tray than the outer portion that rests on the conveyer systems 227A and 227B. The conveyer system 227C is functionally similar to the conveyer systems 227A and 227B discussed in relation to FIG. 2B. For example, the conveyer system 227C includes the motorized pulley 247A, a belt 248C, the pulleys 247B, and a belt guard 219C. The first support rail 220 forms a cutout 225 on a side closest to the mounting plate 232. The cutout 225 allows for additional clearance for equipment, such as optical inspection elements or illumination sources, similar to the gap 224 of the second support rail 222 discussed in relation to FIG. 2A.

In some embodiments, the first support rail 220 includes more than one conveyer system 227. Multiple conveyer systems 227 may beneficially improve control of the movement of the transport media and UUTs and may account for variations in dimensions of the transport media and UUTs.

FIG. 2D depicts a trimetric view of the adjustment system 101A from FIG. 2A with a different transport media and UUT type, according to some embodiments. In particular, FIG. 2D shows the substrate tray 110 disposed on the adjustment system 101A.

The substrate 112 is disposed on the substrate tray 110. The substrate tray dispenser 108 (FIG. 1A) may feed substrate trays 110 to the system 100 (FIG. 1A). The second motion system 228 is used to receive the substrate tray 110 from the substrate tray dispenser 108. The substrate tray 110 may be disposed on the belt 248A, 248B, 248C. For example, the belt 248A, 248B, 248C may support outer portions or edges of the substrate tray 110. The belt actuators 246 move the belt 248A, 248B, 248C and the substrate tray 110 toward and away from the matrix tray dispenser 108 (e.g., along the x-axis). The adjustment system 101A moves the substrate tray 110 so the inspection system 140 (FIGS. 1A and 1B) can inspect the substrate 112, similar to the matrix tray 104.

### Examples of Unit Under Test (UUT) Alignment Systems

FIG. 3A depicts a trimetric view of the UUT alignment system 105, according to some embodiments. Some parts of the adjustment system 101A (FIG. 2A), such as the tracks 238 and support rails 220 and 222, are not shown for simplification of illustration.

The UUT alignment system 105 rotates the transport media transport system 103 about x, y, and z-axes. The UUT alignment system 105 includes a first rotation system 350 and a second rotation system 354. The first rotation system 350 rotates the mounting plate 232 about a zp-axis of the positioning plate 234, which also includes xp and yp-axes. The second rotation system 354 includes a pivot joint (e.g., a gimbal ball 360) and rotates the mounting plate 232 in relation to the base plate 236 via the pivot joint. The pivot joint allows the mounting plate 232 to move about at least two axes (e.g., the x- and y-axes). In the depicted embodiment, the second rotation system 354 rotates the mounting plate 232 and the positioning plate 234 about an xb-axis and a yb-axis of the gimbal ball 360. The gimbal ball 360 is coupled to the base plate 236, and the positioning plate 234 rests on the gimbal ball 360. The mounting plate 232 and the positioning plate 234 rotate in relation to the base plate 236. In the depicted embodiment, the gimbal ball 360 may be coupled to a corner of the base plate 236 by positioning the gimbal ball 360 in a circular cutout (not shown) in the base plate 236.

The first rotation system 350 includes a first bracket 352A, a second bracket 352B, a rotational actuator 352C, a shaft 352D, a compliant mechanism 352E, and a third bracket 352F. The first bracket 352A is coupled to the mounting plate 232 while the second bracket 352B and the third bracket 352F are coupled to the positioning plate 234. The rotational actuator 352C is coupled to the positioning plate 234 via the third bracket 352F. Alternatively, the rotational actuator 352C may be coupled directly to the positioning plate 234 using fasteners, welds, or adhesives, or combinations thereof. The rotational actuator 352C may be a linear actuator, such as a mechanical or electro mechanical, hydraulic, pneumatic, or piezoelectric linear actuator and is configured to cause rotation of the mounting plate 232 in relation to the positioning plate 234 about the z-axis. The rotational actuator 352C pushes the third bracket 352F axially along a shaft 352D to engage the first bracket 352A. The third bracket 352F pushes the first bracket 352A towards the second bracket 352B and compresses the compliant mechanism 352E. Since the positioning plate 234 is fixed in relation to the mounting plate 232, pushing the first bracket 352A, which is coupled to the mounting plate 232, rotates the mounting plate 232 about the z-axis in relation to the positioning plate 234. The compliant mechanism 352E couples the first bracket 352A to the second bracket 352B. The compliant mechanism 352E is compressed when the rotational actuator 352C moves the first bracket 352A towards the second bracket 352B. When the rotational actuator 352C retracts the shaft 352D, the compliant mechanism 352E expands and pushes the first bracket 352A away from the second bracket 352B and may return the mounting plate 232 to a starting position. The first rotation system 350 is further discussed in relation to FIGS. 3D and 3E. The rotational movement of the mounting plate 232 about the z-axis allows transport media, such as the matrix tray 104, to be rotated about the z-axis for better positioning of the UUT for inspection.

The first rotation system 350 further includes at least one arched guide 362 to guide the rotation of the mounting plate 232. As shown in FIG. 3A, three arched guides 362 are used. The arched guides 362 include corresponding elements on the mounting plate 232 and the positioning plate 234. The arched guides 362 of the first rotation system 350 are further discussed in relation to FIGS. 3B-3D.

The second rotation system 354 includes a first actuator 356A having a first shaft 357A, a second actuator 356B having a second shaft 357B, a plurality of compliant mechanisms 358 (such as expansion springs), a plurality of compliant mechanism standoffs 359, and the gimbal ball 360. The actuators 356A and 356B are coupled to the positioning plate 234 on a side opposite the gimbal ball 360, and at opposite corners. The actuators 356A and 356B may be coupled to the positioning plate 234 through brackets, fasteners, welds, adhesives, or a combination thereof. The actuators 356A and 356B and the shafts 357A and 357B are used to rotate the positioning plate 234 about the gimbal ball 360.

Each of the plurality of compliant mechanisms 358 is associated with either the actuator 356A or 356B. The compliant mechanism standoffs 359 are coupled to a second side of the positioning plate 234 adjacent to the actuators 356A and 356B. One end of each of the plurality of compliant mechanisms 358 is coupled to one of the plurality of compliant mechanism standoffs 359 and the other end of each of the plurality of compliant mechanisms 358 is coupled to the base plate 236. Thus, the compliant mechanism standoffs 359 in conjunction with the base plate 236 places a tension on each of the plurality of compliant mechanisms 358 that allows the positioning plate 234 to move closer to the base plate 236. The actuators 356A and 356B may then be used to push the positioning plate 234 along the shafts 357A and 357B. The actuators 356A and 356B, by pushing on the positioning plate 234, rotate the positioning plate 234 and a UUT disposed thereon, such as the matrix tray 104, about the gimbal ball 360 and, as a result, the x-axis and y-axis. Further, the compliant mechanisms 358 provide a compressive force to allow the positioning plate 234 to rotate back to a predetermined position. This rotational movement of the positioning plate 234 and the UUT is discussed further in relation to FIGS. 3F-3K.

The second rotation system 354 may further include a rotation lock 370 to hold a position or orientation of the positioning plate 234 in relation to the base plate 236. The rotation lock 370 includes a rotation lock shaft 371A and a rotation lock actuator 371B. The rotation lock shaft 371A is coupled to the base plate 236 through a pivoted support, such as through a gimbal, which permits rotation of the rotation lock shaft 371A in relation to the base plate 236. For example, an end of the rotation lock shaft 371A may include a socket that is coupled to a ball joint of the base plate 236. In the depicted embodiment, the rotation lock shaft 371A is coupled to a mounting protrusion 337 of the base plate 236, which sticks out from under a side of the mounting plate 232.

The rotation lock actuator 371B is coupled to the positioning plate 234. The rotation lock actuator 371B engages the rotation lock shaft 371A to lock or fix an orientation or position of the UUT alignment system 105. In the depicted embodiment, three rotation lock actuators 371B are shown to allow the actuators 371B to lock the rotation lock shaft 371A at different orientations. The rotation lock actuators 371B are coupled to a plate protrusion 335A of the positioning plate 234, which sticks out from under the mounting plate 232 and is positioned above the mounting protrusion 337. The positioning plate 234 also has a first edge 335B and a second edge 335C, as discussed in relation to FIGS. 3H and 3I.

In the embodiment depicted in FIG. 3A, the first bracket 352A, the second bracket 352B, the rotational actuator 352C, the shaft 352D, and the compliant mechanism 352E are positioned on a same side of the positioning plate 234 as the actuators 356A and 356B and in between the actuators 356A and 356B. In some embodiments, the first bracket 352A, the second bracket 352B, the rotational actuator 352C, the shaft 352D, and the compliant mechanism 352E may be positioned on a different side of the positioning plate 234 or may not be positioned in between the actuators 356A and 356B.

In some embodiments, the first bracket 352A may be coupled to the positioning plate 234 and the second bracket 352B may be coupled to the mounting plate 232. In some embodiments, the rotational actuator 352C may be coupled to the mounting plate 232 and the first bracket 352A may be coupled to the positioning plate 234. In some embodiments, the rotational actuator 352C may directly couple to the first bracket 352A and directly control rotation of the mounting plate 232 such that the compliant mechanism 352E is not used. In such embodiments, the shaft 352D may directly couple to the first bracket 352A and the rotational actuator 352C may extend and retract the shaft 352D to rotate the mounting plate 232.

In some embodiments, any of the plates 232, 234, and 236 may be referred to as an adjustment plate. In some embodiments, any of the actuators 352C, 356A, and 356B may be referred to as an adjustment actuator.

In some embodiments, the pivot joint may be any joint that allows rotation about at least two axes. In some embodiments, the pivot joint may be similar to the pivoted support discussed in relation to the rotation lock shaft 371A.

In some embodiments, the zp-axis may be referred to a central axis. In such embodiments, the positioning plate may be disposed on the central axis and the mounting plate may rotate about the central axis.

In the depicted embodiment, the first and second shafts 357A and 357B include a ball or sphere on an end (e.g., a ball end) that contacts the base plate 236. The ball end allows the shafts 357A and 357B to contact the base plate 236 at different angles. The base plates may include an area or contact plate for the ball end of the shafts 357A and 357B to contact. The contact plates may wear and be replaced. The ball end and the contact plates may each include a non-stick or low-friction material, such as discussed in relation to the tracks 238, to allow the ball end to move in relation to the contact plate.

FIG. 3B depicts a trimetric view of the positioning plate 234, according to some embodiments. The positioning plate 234 includes the arched guides 362 and forms a recess 361. The arched guides 362 each include guide pads 363A coupled to a guide spacer 363B. The guide spacer 363B is coupled to the positioning plate 234. The guide pads 363A engage a guide channel 364 of the mounting plate 232 when the mounting plate 232 rotates in relation to the positioning plate 234, such as discussed in relation to FIGS. 3D and 3E. The guide pads 363A may include a non-stick or low-friction material, such as discussed in relation to the belt guard 219A in FIG. 2B, to allow the guide channel 364 to move in relation to the guide pads 363A. In some embodiments, the guide pads 363A may wear over time and may be replaced. In some embodiments, the guide spacer 363B is not used and the guide pads 363A are coupled directly to the positioning plate 234.

The recess 361 is shaped to correspond to a shape of the gimbal ball 360 (FIG. 3A). For example, the recess 361 of the positioning plate 234 rests on at least a portion of the gimbal ball 360, which fits inside the recess 361. The recess 361 moves about a surface of the gimbal ball 360 and allows the positioning plate 234 and transport media and UUT disposed thereon to rotate about the xb-axis and/or the yb-axis of the gimbal ball 360 as discussed in relation to FIGS. 3F-3K. In some embodiments, the recess 361 may surround a substantial portion of the gimbal ball 360 such that the gimbal ball 360 is held in the recess 361 and would not fall out if the base plate 236 were not present. In some embodiments, the recess 361 or the gimbal ball 360 may include a non-stick or low-friction material. In some embodiments, the gimbal ball 360 may be coupled to the positioning plate 234. In such embodiments, the base plate 236 may form the recess 361.

As shown in FIG. 3B, the plate protrusion 335A forms a rotation lock opening 367. The rotation lock shaft 371A is disposed through the rotation lock opening 367.

FIG. 3C depicts a trimetric view of the mounting plate 232, according to some embodiments. The mounting plate 232 includes the bearing channels 364. The bearing channels 364 are sized to accept the guide pads 363A (FIG. 3B). For example, the guide pads 363A slide along an inner surface of the bearing channels 364 when the mounting plate 232 is rotated. The bearing channels 364 are curved such that they guide movement of the guide pads 363A through the bearing channels 364, and further constrain rotation of the mounting plate 232 to be about the zp-axis (FIG. 3A). In the depicted embodiment, the bearing channels 364 are three arched channels that each have a centerpoint colinear with the zp-axis. Rotation of the mounting plate 232 and transport media with a UUT disposed thereon is further discussed in relation to FIGS. 3D and 3E.

In some embodiments, more or fewer bearing channels 364 may be used. In some embodiments, the guide channel 364 is a single channel that forms a circular channel adjacent to at least two sides of the mounting plate 232. In some embodiments, the guide channel 364 may be a single channel formed connecting the three bearing channels 364 depicted in FIG. 3C. In some embodiments, the centerpoint of bearing channels 364 may not be the colinear with the zp-axis. In some embodiments, the bearing channels 364 are generally curved about the zp-axis. In some embodiments, the bearing channels 364 may be formed by the positioning plate 234 (FIG. 3B) and the arched guides 362 (FIG. 3B) may couple to the mounting plate 232.

FIGS. 3D and 3E depict a top view of the UUT alignment system 105, according to some embodiments. In particular, FIGS. 3D and 3E show the first rotation system 350 rotating the mounting plate 232 as previously discussed. In particular, FIG. 3D shows the mounting plate 232 in a home position (e.g., a first position or a position aligned to the positioning plate 234).

The shaft 352D contacts the first bracket 352A when the mounting plate 232 is in the home position. The rotational actuator 352C moves the shaft 352D toward and away from the first bracket 352A to move the mounting plate 232 to different positions. When the shaft 352D moves toward the first bracket 352A, the shaft 352D pushes the first bracket 352A and the mounting plate 232. The bearing channels 364 move over the guide pads 363A and translate linear movement of the shaft 352D into rotational movement of the mounting plate 232, such as shown in FIG. 3E.

FIG. 3E shows the mounting plate 232 rotated by the first rotation system 350. When the shaft 352D moves the first bracket 352A towards the second bracket 352B, the compliant mechanism 352E is compressed in between. When the shaft 352D moves away from the first bracket 352A, the compliant mechanism 352E moves the first bracket 352A with the shaft 352D and towards the rotational actuator 352C. Thus, the rotational actuator 352C is used to rotate the mounting plate 232.

The compliant mechanism 352E includes an elastic object that stores mechanical energy, such as a compression spring. For example, the compliant mechanism 352E stores mechanical energy when the compliant mechanism 352E is compressed between the first bracket 352A and the second bracket 352B. When the shaft 352D retracts, the compliant mechanism 352E exerts the stored mechanical energy (e.g., a force) on and moves the first bracket 352A, which in turn moves the mounting plate 232 in relation to the positioning plate 234. Thus, the compliant mechanism 352E is “biased” to move the first bracket 352A in a direction away from the second bracket 352B and rotate the mounting plate 232 in relation to the positioning plate 234 about the z-axis. The rotation of the mounting plate 232 causes transport media, such as the matrix tray 104, that is disposed on the adjustment system 101A coupled to the surface of the mounting plate 232 as described above to also rotate about the z-axis.

In some embodiments, the rotational actuator 352C moves the positioning plate 234 in a direction opposite the bias direction of the compliant mechanism 352E. In some embodiments, the rotational actuator 352C attaches directly to the first bracket 352A, such as through a pivoted support, for example a gimbal, which permits rotation of first bracket 352A in relation to the shaft 352D. In such embodiments, the second bracket 352B and the compliant mechanism 352E may not be needed. In some embodiments, the compliant mechanism 352E may be expanded and consequently “biased” to move the first bracket 352A in a direction towards the second bracket 352B.

FIGS. 3F and 3G depict front and left side views, respectively, of the UUT alignment system 105, according to some embodiments. In particular, FIGS. 3F and 3G show the adjustment system 101A in a starting position. In the depicted embodiment, the actuators 356A and 356B retract the shafts 357A and 357B simultaneously to rotate or “tip” the first edge 335B of the positioning plate 234 about the x-axis downward towards the base plate 236, such as shown in FIGS. 3H and 3I. The compliant mechanism 358 is coupled to the plates 234 and 236 near each actuator 356A and 356B. The compliant mechanisms 358 are biased to pull the positioning plate 234 in a direction towards the base plate 236 as the shafts 357A and 357B retract, such as discussed in relation to FIGS. 3H and 3I. The actuators 356A and 356B may move the positioning plate 234 in a direction opposite the bias direction of the compliant mechanism 358.

Alternatively, actuator 356B may retract shaft 357B while the actuator 356A remains stationary on the shaft 357A. Such actuation results in a rotation or “tilt” of the positioning plate 234 and a UUT disposed thereon about the y-axis. This allows for greater inspection accuracy as the UUT may be positioned optimally during inspection.

FIGS. 3H and 3I depict front and left side views, respectively, of the UUT alignment system 105, according to some embodiments. In particular, FIG. 3H and 3I show the adjustment system 101A rotated about the xb-axis in a first maximum adjustment position. The shafts 357A and 357B are fully retracted and a length of the first edge 335B is closest to the base plate 236. As the actuators 356A and 356B retract the shafts 357A and 357B, the recess 361 of the positioning plate 234 slides over the gimbal ball 360 to rotate the positioning plate 234 and transport media with a UUT disposed thereon.

In some embodiments, only one compliant mechanism 358 is used to pull the positioning plate 234 in the bias direction towards the base plate 236. In some embodiments, the compliant mechanisms 358 are not used and a weight of the adjustment system 101A (FIG. 1A) moves the positioning plate 234 toward the base plate 236. In some embodiments, the actuators 356A and 356B may directly couple to the base plate 236 and directly control rotation of the positioning plate 234 about the xb and yb-axes of the gimbal ball 360 such that the compliant mechanism 358 is not used. In such embodiments, the shafts 357A and 357B may be directly coupled to the base plate 236 and the actuators 356A and 356B may extend and retract the shafts 357A and 357B to rotate the mounting plate 232.

FIGS. 3J and 3K depict front and right side views, respectively, of the UUT alignment system 105, according to some embodiments. In particular, FIGS. 3J and 3K show the adjustment system 101A rotated about the yb-axis in a second maximum adjustment position. The second shaft 357B is fully retracted while the first shaft 357A is extended (or fully extended). A length of the second edge 335C is closest to the base plate 236. The recess 361 of the positioning plate 234 slides over the gimbal ball 360 as the actuator 356B retracts the second shaft 357B.

Although FIGS. 3H-3K discuss rotation about a single axis, the UUT alignment system 105 may rotate the adjustment system 101A about both the xb and yb-axes by retracting the second shaft 357B while the first shaft 357A is extended. The shafts 357A and 357B may also be extended and retracted to different positions to rotate the adjustment system 101A about both the xb and yb-axes and to orient the positioning plate 234 at different positions.

### Additional Examples of Adjustment Systems

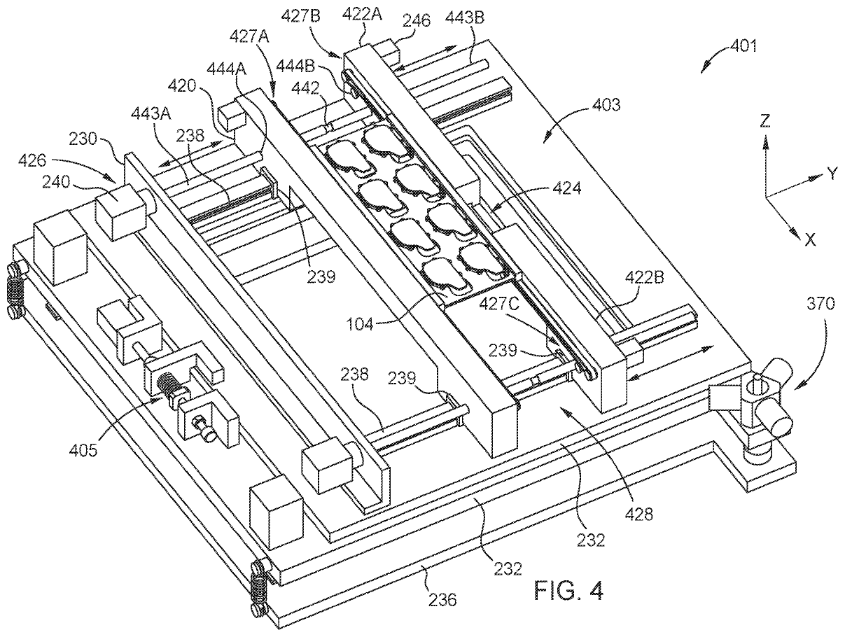

FIG. 4 depicts a trimetric view of an adjustment system 401, according to some embodiments. The adjustment system 401 functions similar to the adjustment system 101A, except as noted. For example, the adjustment system 401 may be used with the positioning system 101B (FIG. 1A).

The adjustment system 401 includes a transport media transport system 403 and a media UUT alignment system 405. The transport media transport system 403 includes a first support rail 420, second support rail 422 (e.g., sub-rails 422A and 422B), first motion system 426, second motion system 428, mounting rail 230, mounting plate 232, and positioning plate 234. The UUT alignment system 405 is similar to the UUT alignment system 105 discussed in relation to FIGS. 3A-3K, except as noted.

The first motion system 426 uses the support rails 420 and 422 to grasp transport media, such as the matrix tray 104. The support rails 420 and 422 include guides 239 to guide movement of the support rails 420 and 422 along the tracks 238. Thus, the support rails 420 and 422 are movably coupled to the tracks 238. The rail actuators 240 move the support rails 420 and 422 using a shaft 442 coupled to each rail actuator 240. The rail actuators 240 are also coupled to the mounting rail 230, which is coupled to the mounting plate 232. Each shaft 442 includes a first threaded portion 443A to engage a first threaded hole 444A formed by the first support rail 420 or a threaded insert (not shown). The threaded hole 444A may be similar to the threaded hole 244 discussed in relation to FIG. 2A. Each shaft 442 further includes a second threaded portion 443B to engage a second threaded hole 444B formed by the second support rail 422 or a threaded insert (not shown).

Threads of the threaded portions 443A and 443B and the threaded holes 444A and 444B are configured such that when the rail actuators 240 rotate the shafts 442 in a first direction (e.g., clockwise), the support rails 420 and 422 move apart from another. When the rail actuators 240 rotate the shafts 442 in a second direction (e.g., counter-clockwise), the support rails 420 and 422 move towards one another. This configuration of the first and second support rails 420 and 422 adjusts to a desired width, such as the width of transport media, such as the matrix tray 104 or the substrate tray 110. Such a capability allows for various types of UUTs to be inspected using only one system, leading to a reduction in cost and equipment complexity. In some embodiments, the threads of the threaded portion 443A and the threaded hole 444A may be a right-handed thread and the threads of the threaded portion 443B and the threaded hole 444B may be a left-handed thread, or vice-versa.

The second support rail 422 includes a first sub-rail 422A and a second sub-rail 422B and forms a gap 424 between the sub-rails 422A and 422B. The gap 424, configured similarly to gap 224, may provide clearance for an end effector of a robot (not shown). The robot may be used to position UUTs on the matrix tray 104 such as by an Equipment Front End Module (EFEM). The gap 424 may provide additional clearance (e.g., along the z-axis) for other equipment, such as inspection optics or illumination sources, to clear the second support rail 422. In some embodiments, the second support rail 422 is a single support rail or unitary body, similar to the second support rail 222 discussed in relation to FIG. 2A.

The second motion system 428 is coupled to the support rails 420 and 422. In the embodiment depicted in FIG. 4, the second motion system 428 includes conveyer systems 427 (e.g., a first conveyer system 427A, a second conveyer system 427B, and a third conveyer system 427C). The conveyer systems 427 are positioned in parallel to each other and operate such that belt motion along the conveyer systems is along the same axis (e.g., x-axis). The conveyer systems 427 also are similar to the conveyer systems 227, except as noted. The first conveyer system 427A is coupled to and runs a length of the first support rail 420. The second and third conveyer systems 427B and 427C are coupled to the second support rail 422. The second conveyer system 427B is coupled to and runs a length of the sub-rail 422A. The third conveyer system 427C is coupled to and runs a length of the sub-rail 422B. The second motion system 428, like the second motion system 228, is configured to provide linear motion of transport media, such as the matrix tray 104, along the axis (e.g., x-axis) of the second motion system 428.

### Example Methods of Inspecting UUTs

FIGS. 5A-5C depict flowcharts of methods 500, 520, and 540 of inspecting media, according to some embodiments. FIGS. 6A-6H depict different views of the system 100 in operations of the methods 500, 520, and 540, according to some embodiments. In particular, FIGS. 6A-6H schematically illustrate views of the system 100 at different stages of the methods 500 depicted in FIGS. 5A, 520 depicted in FIG. 5B, and 540 depicted in Figure C using the matrix tray 104 as the media, according to some embodiments. Therefore, FIGS. 5A-5C and FIGS. 6A-6H are herein described together for clarity.

As shown in the embodiment in FIG. 6A, and in operations 502, 522, and 542 of the methods 500, 520, and 540 in FIGS. 5A-5C, the transport media (e.g., the matrix tray 104 with UUTs thereon) is positioned on the system 100 (FIG. 1A), such as on the second motion system 228 of the system 100. In particular, the matrix tray 104 is resting on the belts 248A and 248C of the conveyer systems 227A and 227B, respectively. The matrix tray 104 may be loaded on the second motion system 228 prior to the method 500, such as discussed in relation to FIG. 1A by dispensers (e.g., dispenser 102 or dispenser 108) or by an EFEM.

In operation 504 of FIG. 5A, and as shown in FIG. 6A, the transport media (e.g., the matrix tray 104) is moved along a length of the first and second support rails 220 and 222 to a first location using at least one of the conveyer systems 227A, 227B, and 227C. In the embodiment depicted in FIG. 6A, the second motion system 228 moves the matrix tray 104 towards the inspection system 140 (FIG. 1A) until the matrix tray 104 contacts a barrier 680 (e.g., a first barrier 680A), such as an extendable member 681A of the first barrier 680A. The barrier 680 extends to prevent further motion of the matrix tray 104 along the conveyer systems 227A and 227B past a desired point (e.g., at the barrier 680). In some embodiments, the barrier 680 may be referred to as a gate or a fence. The first barrier 680A may be coupled to the first support rail 220 and includes the extendable member 681A, which is coupled to a barrier actuator 681B. The barrier actuator 681B extends and retracts the extendable member 681A orthogonally to a motion path of the matrix tray 104 along the conveyer systems 227A and 227B. For example, when retracted, the extendable member 681A may be retracted inside a barrier recess 623 of the second support rail 222 to allow the matrix tray 104 to proceed through the second motion system 228. When extended, the extendable member 681A may be positioned over the belt 248A or over an area in between the belts 248A of the conveyer systems 227B and 227C to limit movement of the matrix tray 104 to move on the second motion system 228. The motorized pulley 247A rotates to move the belts 248A, which in turn moves the matrix tray 104.

Several means may be used to determine if the matrix tray 104 contacts the first barrier 680A. In some embodiments, an angular position of the motorized pulley 247A may be monitored, for example, by the system controller 199 (FIG. 1A). The first barrier 680A may be actuated when the angular position of the motorized pulley 247A reaches a predetermined value, the predetermined value dependent on the length of the belts, the length of the matrix tray 104, and the circumference of the pulleys. In some embodiments, a sensor may be used, for example, as an input to the system controller 199. In some embodiments, the sensor may be a contact sensor that senses electrical contact on a circuit board or a magnetic field to determine if the matrix tray 104 contacts the first barrier 680A. In some embodiments, the extendable member 681A may use a flex sensor or strain gauge to detect if the extendable member 681A deforms, such as by changing a resistance of the flex sensor or strain gauge. In some embodiments, a proximity sensor may be used, such as an inductive, capacitive, ultrasonic, infrared, or magnetic proximity sensor, to name a few. In some embodiments, the second motion system 228 may move the matrix tray 104 a predetermined distance to a predetermined location and the first barrier 680A may function as a backstop to prevent overshooting the predetermined location. For example, the system controller 199 may control movement of the belt 248A by controlling rotation of the motorized pulley 247A, such as through an encoder. Alternatively, contact with barrier 680 may be measured by columns of UUTs on matrix tray 104 rather than the matrix tray 104 itself. As belt index motion errors are cumulative, barriers (e.g., barrier 680) may be used at every column, every other column, or between any desired number of columns of UUTs on the matrix tray 104.

The matrix tray 104 includes several eyepieces 106 (e.g., UUTs). In the embodiment depicted in FIG. 6A, the matrix tray 104 includes eight eyepieces (e.g., first to eighth eyepieces 106A-H). Each eyepiece 106 is associated with a coordinate system. For example, the first eyepiece 106A has a coordinate system xe1, ye1, and ze1, the second eyepiece 106B has a coordinate system xe2, ye2, and ze2, and so forth. The coordinate system of each eyepiece 106 may be oriented slightly different from other eyepieces 106 due to manufacturing tolerances and such. For example, the xe1, ye1, and ze1-axes of the first eyepiece 106A may each be oriented such that they are not parallel to corresponding xe2, ye2, and ze2-axes of the second eyepiece 106B. The eyepieces 106A-H and respective coordinate systems are discussed further in relation to subsequent figures.

In some embodiments, the barrier actuator 681B may be a linear actuator, such as a mechanical or electro-mechanical, hydraulic, pneumatic, or piezoelectric linear actuator, or a combination thereof. In such embodiments, the linear actuator may linearly move the extendable member 681A into and out of the path of the matrix tray 104, such as away from and towards the linear actuator.

Alternatively, the barrier actuator 681B may be a rotary actuator such as a servo or servomotor, a stepper motor, rack-and-pinion actuator, a vane actuator, a helix actuator, a planetary actuator, a linear cylinder, a scotch-yoke actuator, a sprocket actuator, a bladder actuator, or a direct-drive motor, to name a few options. In such embodiments, the rotary actuator may rotate the extendable member 681A into and out of the path of the matrix tray 104.

The extendable member 681A may be any suitable structure. In embodiments where the barrier actuator 681B is a linear actuator, the extendable member 681A may be a rod or shaft that may be moved into and out of the path of the matrix tray 104. In embodiments where the barrier actuator 681B is a rotary actuator, the extendable member 681A may be an L-shaped bracket and the bottom of the “L” may be rotated into and out of the path of the matrix tray 104.

In some embodiments, the operations 502, 522, and 542 of the methods 500, 520, and 540 in FIGS. 5A-5C include adjusting a distance (e.g., the gap 221 in FIG. 2A) between the first and second support rails 220 and 222 using the rail actuators 240 (FIG. 2A). In such embodiments, the distance may be adjusted to receive the transport media on the conveyer system 227.

In the embodiment depicted in FIG. 6B, the first motion system 226 moves the first support rail 220 towards the second support rail 222 to grasp the matrix tray 104. In some embodiments of the method 500, the first motion system 226 may grasp the matrix tray between the inner sides of the first and second support rails 220 and 222 by using the rail actuators 240 (FIG. 2A) to reduce a distance (e.g., the gap 221 in FIG. 2A) between the first and second support rails 220 and 222. Once the matrix tray 104 is secured between the support rails 220 and 222, the matrix tray 104 is effectively fixed to the mounting plate 232 such that the matrix tray 104 moves with the mounting plate 232.

The first motion system 226 may use several means to determine whether the matrix tray 104 is secured between the support rails 220 and 222. For example, a current of the rail actuators 240 (FIG. 2A) may be monitored, a sensor may be used, or the first support rail 220 may be moved a predetermined distance, such as previously discussed in relation to the second motion system 228, the matrix tray 104, and the first barrier 680A.

The extendable member 681A of the first barrier 680A may be retracted before or after the matrix tray 104 is grasped. The extendable member 681A may remain extended after the matrix tray 104 is grasped.

In method 520, once the transport media (e.g., the matrix tray 104) and related UUTs are moved into a position for inspection by the conveyer systems 227A and 227B, the barrier 681 is used to stop the transport media, preferably at the first row of UUTs in the matrix tray 104. In operation 524, the actuators 114A and 114B adjust the alignment camera (e.g., imaging system 146) to a position to acquire a fiducial image of an initial UUT of an initial column of the matrix tray 104. The alignment camera and the fiducials 683 then determine the amount of rotation about the z-axis needed to align the matrix tray 104 for inspection. The rotational actuator 352C then rotates the positioning plate 234 thus also rotating the matrix tray 104. In operation 528, the distance sensor is used to determine the distance between the matrix tray 104 and the inspection system 140 at three distinct points on a UUT. This information determines the amount of rotation needed about the x-axis and the y-axis by finding the orientation of an XY plane of the matrix tray 104. The first and second actuators 357A and 357B then correct the angular rotation about the x-axis and y-axis via a pivot joint (e.g., gimbal ball 360). Once the matrix tray 104 is re-aligned, the UUT is inspected by the inspection system 140. After inspection of the UUT, the first and second actuators 114A and 114B adjust the matrix tray 140 such that a subsequent UUT in the initial column as the initial UUT is aligned with the inspection system 140. The subsequent UUT undergoes the same re-alignment procedure as the initial UUT. Once all of the UUTs in the initial column are inspected, the conveyer systems 227A and 227B adjust the matrix tray 140 such that a subsequent column of UUTs may be inspected by the inspection system 140 in a similar manner as the initial column of UUTs.

In some embodiments, such as shown operation 524 of FIG. 5B and as discussed in relation to FIGS. 1A and 1B, the positioning system 101B moves the movable plate 119 in relation to the fixed plate 118 using the first positioning actuator 114A. The positioning system 101B also moves the fixed plate 118 in relation to the base plate 236 using the second positioning actuator 114B. In such embodiments, the positioning system 101B may move the adjustment system 101A, which is coupled to the movable plate 119.

In the embodiment depicted in FIGS. 6C and 6D, and in operations 504, 524, 526, 528, and 544 of FIGS. 5A-5C, the inspection system 140 is used with the UUT alignment system 105 to position, orient, and align the matrix tray 104 prior to inspection by the inspection device 142. In particular, a distance to a surface of the matrix tray 104 is measured using the distance sensor 144, the matrix tray 104 is re-oriented, an alignment of the matrix tray 104 is measured using the imaging system 146, and the matrix tray 104 is re-aligned.

The UUT alignment system 105 aligns the matrix tray 104 based on each eyepiece 106 (e.g., the first to eighth eyepieces 106A-H in FIG. 6A). FIGS. 6C and 6D show the first eyepiece 106A being inspected by the inspection system 140, although the operations and processes described are applicable to the second to eighth eyepieces 106B-H. The extendable member 681A of the first barrier 680A is extended and a second barrier 680B is shown with an extendable member 681A that is retracted. The second barrier 680B may be coupled to the second support rail 222 and is discussed in relation to FIG. 6H.

The matrix tray 104 is re-oriented as follows. The distance sensor 144 measures the distance to at least three points on the first eyepiece 106A (e.g., a first distance point 682A, a second distance point 682B, and a third distance point 682C) to define an x-y plane. The positioning system 101B moves the adjustment system 101A to a position such that the distance sensor 144 is directly overhead and roughly perpendicular to the matrix tray 104 at a point to be measured on the first eyepiece 106A. For example, the distance sensor 144 is shown in FIGS. 6C and 6D over the first distance point 682A. After the distance sensor 144 measures a distance to the first distance point 682A, the positioning system 101B moves the movable plate 119 and the fixed plate 118 using the first and second positioning actuators 114A and 114B as described in operations 524 and 526 of FIG. 5B and shown in FIGS. 1A and 1B. The positioning system 101B may move the adjustment system 101A so the distance sensor 144 is over the second distance point 682B and measures a distance to the second distance point 682B. This process is repeated for the third distance point 682C. In some embodiments, the distance sensor 144 may move in relation to the first eyepiece 106A.

The system controller 199 determines an orientation of the first eyepiece 106A (e.g., the first eyepiece coordinate system xe1, ye1, and ze1 discussed in relation to FIG. 6A) based on the distances measured. In operations 528 and 544 shown in FIGS. 5B and 5C, and as shown in FIGS. 6C-6E, the positioning plate 234 is moved using an actuator (e.g., the first actuator 356A and/or the second actuator 356B) to adjust an orientation of the transport media (e.g., the matrix tray 104). The positioning plate 234 may be moved if the orientation of the eyepiece coordinate system is not aligned with the orientation of a reference coordinate system. The UUT alignment system 105 rotates the matrix tray 104 to align a z-axis of the first eyepiece 106A (e.g., ze1) with a z-axis of the reference coordinate system, such as within +/−5 degrees, such as within +/−2 degrees, such as within +/−1 degree, such as within +/−0.5 degrees, such as within +/−0.25 degrees, such as within +/−0.08333 degrees (5 arc minutes). In some embodiments, the method 540 in FIG. 5C includes rotating the matrix tray 104 about a first and second axis of the reference coordinate system, such as about x and y-axes, to align the z-axis of the first eyepiece 106A. The reference coordinate system is stationary (e.g., fixed) in relation to the matrix tray 104 and moving parts of the UUT alignment system 105.

In the depicted embodiment, the reference coordinate system is the coordinate system of the gimbal ball 360 (e.g., the xb and yb axes). If the distance to any of the three distance points 682A-C is different from the distance to the other distance points 682A-C, then the UUT alignment system 105 rotates the matrix tray 104 about the xb and yb-axes of the gimbal ball 360 to align the matrix tray 104 such that a plane formed by at least a portion of matrix tray 104 (e.g., the first eyepiece 106A) is roughly parallel to a plane formed by the x and y-axes of a reference coordinate system (e.g., coordinate system of inspection system 140). In some embodiments, the distance to each of the three distance points 682A-C after adjustment (or for the matrix tray 104 to not need adjustment) may be within 5 arc minutes. In some embodiments, each of the distances to each of the three distance points 682A-C is compared to a reference distance and the matrix tray 104 is rotated until each of the distances are within 5 arc minutes.

The x- and y-axes of the coordinate systems are aligned as follows. The first and second actuators 356A and 356B move the first and second shafts 357A and 357B, respectively, as discussed in relation to FIGS. 3F-3K. For example, if the distance to the first distance point 682A is greater than the distance to the second and third distance points 682B and 682C, then the second actuator 356B may extend the second shaft 357B or retract the first shaft 357A to align the first distance point 682A with the second and third distance points 682B and 682C. If the distance to the second distance point 682B is greater than the distance to the first and third distance points 682A and 682C, and the distance to the first distance point 682A is less than the distance to the second distance point 682B and more than the distance to the third distance point 682C, then the first and second actuators 356A and 356B may extend the first and second shafts 357A and 357B such that the first shaft 357A is extended more than the second shaft 357B.

Once the x- and y-axes are aligned, the rotation lock 370 holds the orientation of the matrix tray 104. For example, the rotation lock actuators 371B engage the rotation lock shaft 371A to lock or fix an orientation or position of the matrix tray 104. The rotation lock 370 ensure the matrix tray 104, and in particular, the first eyepiece 106A, remains in the plane formed by at least a portion of matrix tray 104, for example, if the matrix tray 104 moves or is rotated.

The system controller 199 further determines the alignment of the first eyepiece 106A based on features of the first eyepiece 106A. If the eyepiece coordinate system is not aligned with the reference coordinate system, the UUT alignment system 105 rotates the matrix tray 104 to align x and y-axes of the first eyepiece 106A (e.g., xe1 and ye1) with x and y-axes of the reference coordinate system (e.g., xb and yb), such that each axis is within +/−5 degrees, such that each axis is within +/−2 degrees, such that each axis is within +/−1 degree, such that each axis is within +/−0.5 degrees, such that each axis is within +/−0.25 degrees, such as +/−0.08333 degrees (5 arc minutes).

In the depicted embodiment, the x and y-axes of the coordinate systems are aligned as follows. The features of the first eyepiece 106A on which alignment is based are fiducials (e.g., a first fiducial 683A and a second fiducial 683B) or fiducial markers. The fiducials 683A to 683B are reference points used for measurements. The imaging system 146 determines the alignment of the matrix tray 104 based on the fiducials 683A and 683B. For example, the imaging system 146 compares the actual location of the fiducials 683A to 683B to an expected location stored in a memory (e.g., a memory 850 in FIG. 8) of the system controller 199. The imaging system 146 determines the “offset” or angle to which the matrix tray 104 must be moved or rotated to align the matrix tray 104. The rotational actuator 352C moves the shaft 352D to rotate the mounting plate 232, such as discussed in relation to FIGS. 3D and 3E. The fiducials may be aligned to a positional tolerance or vector tolerance (e.g., the rotation alignment of a vector connecting the fiducials about the z-axis) of within +/−5 arc minutes. Some embodiments of the method 520 in FIG. 5B include rotating the mounting plate 232 in relation to the positioning plate 234 using the rotational actuator 352C. In some embodiments, the system controller 199 determines the alignment of the matrix tray 104 using the imaging system 146 as an input, such as discussed in relation to FIG. 8.

In some embodiments, the positioning system 101B moves the adjustment system 101A to align the fiducials 683A to 683B. In some embodiments, the imaging system 146 may be a camera or video camera. In some embodiments, the imaging system 146 may be a fiducial camera. In some embodiments, the imaging system 146 may use any of visible light, infrared light, or ultraviolet light to capture the position of the fiducials 683A to 683B.

In the embodiment depicted in FIGS. 6C and 6D, the second fiducial 683B is near the second distance point 682B, such as co-located or overlapping. In some embodiments, the fiducials 683 and distance points 682 may be spatially separated, such as not co-located or overlapping.

In some embodiments, the positioning system 101B moves the adjustment system 101A such that the imaging system 146 is directly overhead and roughly perpendicular to the first eyepiece 106A. In some embodiments, the adjustment system 101A remains in a position from a previous operation, such as a position after aligning the z-axis of the first eyepiece 106A with the z-axis of the reference coordinate system. In some embodiments, the imaging system 146 may move in relation to the first eyepiece 106A.

The matrix tray 104 is inspected by the inspection device 142. In the depicted embodiment, the matrix tray 104 is inspected after being oriented and aligned by the UUT alignment system 105. The inspection device 142 inspects a surface of the first eyepiece 106A, such as a surface within a line of sight of the inspection device 142. Some embodiments of the method 540 in FIG. 5C further includes inspecting the surface of the first eyepiece 106A. In some embodiments, the inspection device 142 measures a profile of the surface. In some embodiments, the inspection device 142 measures characteristics of the surface, such as measuring a transparency or reflectance, such as analyzing elemental composition (e.g., performing energy dispersive spectroscopy (EDS)), such as inspecting for cracks, such as creating a two or three-dimensional map of the surface to name a few examples.

In some embodiments, the inspection device 142 may be a metrology system. In some embodiments, the inspection device 142 may interface with a metrology system. In some embodiments, embodiments, the inspection device 142 may be at least one of a transparency meter, reflectance meter, illuminance meter, a scanning electron microscope (SEM), transmission electron microscope (TEM), two or three-dimensional optical profiler, laser interferometer, or laser scanner to name a few examples.

In some embodiments, the positioning system 101B moves the adjustment system 101A such that the inspection device 142 is directly below or roughly perpendicular (or orthogonal) to the first eyepiece 106A. In some embodiments, the inspection device 142 may move in relation to the first eyepiece 106A.

In some embodiments, the distance sensor 144 may be a displacement sensor. In some embodiments, the distance sensor 144 may be a non-contact sensor such as an optical displacement sensor, linear proximity sensor, laser displacement sensor, or ultrasonic displacement sensor to name a few examples. In some embodiments, the distance sensor 144 may be a confocal sensor.

The inspection device 142 uses the reference coordinate system to inspect eyepieces 106 on the matrix tray 104. In the depicted embodiment, the reference coordinate system used to orient and align the matrix tray 104 is the coordinate system of the gimbal ball 360. In such embodiments, the inspection system 140 may translate the coordinate system of the gimbal ball 360 to a coordinate system of the inspection device 142 if the coordinate systems of the gimbal ball 360 and the inspection device 142 are not aligned, such as through the system controller 199 (FIG. 1A). In some embodiments, the reference coordinate system may be a coordinate system of the inspection device 142. In such embodiments, the matrix tray (e.g., the first eyepiece 106A) may be aligned to the coordinate system of the inspection device 142. In some embodiments, the reference coordinate system may be a coordinate system of the distance sensor 144 or the imaging system 146.

In the depicted embodiment, the UUT alignment system 105 aligns the matrix tray 104 prior to inspection of each eyepiece 106, which beneficially allows the matrix tray 104 to be manufactured with larger dimensional tolerances than current matrix trays. For example, the matrix tray 104 may have a wider flatness or parallel tolerance than JEDEC standard. Additionally, the transport media transport system 103 may accommodate matrix trays 104 of various dimensions.

In some embodiments, the media alignment system 105 does not align the matrix tray 104 prior to inspection of each eyepiece 106. For example, a dimensional tolerance of the matrix tray 104 may be such that the matrix tray 104 need only be aligned to one eyepiece 106, every other eyepiece 106, or only a portion of the eyepieces 106. In some embodiments, the distance points 682A-C may be fiducials 683 or fiducial markers.

FIG. 6E depicts a cross-sectional view of FIG. 6C, according to some embodiments. In particular, FIG. 6E shows the positioning of the matrix tray 104 and the first eyepiece 106A while the distance sensor 144 measures a distance to the first eyepiece 106A. Some parts of the system 100, such as the UUT alignment system 105, tracks 238, and the guides 239, are not shown for simplification of illustration.

The matrix tray 104 is shown resting on the conveyer system 227B and contacting the first barrier 680A. The first eyepiece 106A is shown below the distance sensor 144 and the distance sensor 144 is shown measuring a distance (d) to a distance point on the first eyepiece 106A. Some embodiments of the method 520 in FIG. 5B further include measuring a first distance to the first distance point 682A (FIG. 6D) and a second distance to the second distance point 682B (FIG. 6D) using the distance sensor 144. The actuators 356A and 356B (FIG. 3A) may move the positioning plate 234 via the gimbal ball 360 based on the first and second distance measurements.

The first eyepiece 106A is shown above the inspection device 142. The inspection device 142 maintains a line of sight through the openings 133A-C and openings 117 (FIG. 1A) when inspecting the first eyepiece 106A.

In some embodiments, parts of the inspection system 140 (e.g., the inspection device 142, the distance sensor 144, or imaging system 146) may move left and right (as shown on the page) in relation to the first eyepiece 106A. In some embodiments, the parts of the inspection system 140 may move into and out of the page in relation to the first eyepiece 106A. In some embodiments, the parts of the inspection system 140 may move up and down (as shown on the page) in relation to the first eyepiece 106A. The parts of the inspection system 140 may move through an actuator, such as a rotary or linear actuator similar to the actuators discussed in relation to FIG. 3A.

FIG. 6F depicts a second eyepiece 106B of the matrix tray 104 being inspected. In particular, FIG. 6F depicts the operations discussed in relation to FIGS. 6C-6E being performed on the second eyepiece 106B, which is adjacent to the first eyepiece 106A.

The inspection system 140 and the UUT alignment system 105 are used to orient and align the matrix tray 104 prior to inspection by the inspection device 142. The positioning system 101B positions the second eyepiece 106B to be measured by the inspection system 140, for example, by moving the adjustment system 101A along the y-axis (FIG. 1A) using the second positioning actuator 114B. The second eyepiece 106B is positioned below the distance sensor 144, which measures a distance to distance points 682D-F on the second eyepiece 106B. The distances measured are used to determine an orientation of the second eyepiece 106B (e.g., the second eyepiece coordinate system xe2, ye2, and ze2 in FIG. 6A). The UUT alignment system 105 may orient the matrix tray 104 based on the distances measured, for example, by aligning a z-axis of the second eyepiece 106B (e.g., ze2) with the z-axis of the reference coordinate system. The UUT alignment system 105 aligns the second eyepiece 106B using the first and second actuators 356A and 356B, similar how the first eyepiece 106A is aligned as discussed in relation to FIGS. 6C and 6D.

The second eyepiece 106B further includes a first fiducial 683C and a second fiducial 683D. The imaging system 146 determines the alignment of the matrix tray 104 based on the fiducials 683C and 683D. The UUT alignment system 105 aligns the x and y-axes of the coordinate systems using the rotational actuator 352C, similar to how the first eyepiece 106A is aligned as discussed in relation to FIGS. 6C and 6D. Once the second eyepiece 106B is oriented and aligned, the inspection device 142 inspects a surface of the second eyepiece 106B.

FIG. 6G depicts a fourth eyepiece 106D of the matrix tray 104 being inspected. In particular, FIG. 6G depicts the operations discussed in relation to FIGS. 6C-6E being performed on the fourth eyepiece 106D, which is adjacent to the second eyepiece 106B and catty-corner to the first eyepiece 106A.

In the depicted embodiment, the fourth eyepiece 106D is inspected after the second eyepiece 104B and before a third eyepiece 106C. The second motion system 228 is used to position the matrix tray 104 to inspect the fourth eyepiece 106D. After the second eyepiece 104B is inspected, the extendable member 681A of the first barrier 680A is retracted, the support rails 220 and 222 ungrasp or release the matrix tray 104, and the second motion system 228 moves the matrix tray 104 to position the fourth eyepiece 104D below the distance sensor 144. For example, the second motion system 228 moves the matrix tray 104 along the x-axis (FIG. 1A) and stops when the fourth eyepiece 104D is appropriately positioned. The second motion system 228 may position the matrix tray 104 without use of the positioning system 101B.

The system controller 199 may use open loop control to move the matrix tray 104. In some embodiments, the belt actuators 246 move the belts 248 for a predetermined time, which in turn moves the matrix tray 104 a predetermined distance. In some embodiments, the belt actuators 246 include an encoder that is used to determine a position of the matrix tray 104. In some embodiments, a barrier 680 is used to ensure the fourth eyepiece 106D is positioned below the distance sensor 144, similar to the first barrier 680A discussed in relation to FIG. 6A. In some embodiments, the positioning system 101B is used to move the matrix tray 104 to position the fourth eyepiece 106D below the distance sensor 144.

Once the fourth eyepiece 106D is near or below the distance sensor 144, the support rails 220 and 222 grasp the matrix tray 104 to secure the matrix tray 104 to the adjustment system 101A. The distance sensor 144 measures a distance to distance points 682J-L (distance points 682G-I are associated with a third eyepiece 106C, which may be inspected after the fourth eyepiece 106D) and the UUT alignment system 105 may orient the matrix tray 104 based on the distances measured, for example, by aligning a z-axis of the fourth eyepiece 106D with the z-axis of the reference coordinate system. The imaging system 146 determines the alignment of the matrix tray 104 based on a first fiducial 683G and a second fiducial 683H of the fourth eyepiece 106D (fiducials 683E and 683F are associated with the third eyepiece 106C) and the UUT alignment system 105 aligns the matrix tray 104, and the inspection device 142 inspects a surface of the fourth eyepiece 106D.

The third eyepiece 106C may be inspected prior to the fifth eyepiece 106E using the operations discussed in relation to FIGS. 6C-6E. The positioning system 101B positions the second eyepiece 106B, the UUT alignment system 105 orients the matrix tray 104 using the distance points 682G-I, and the UUT alignment system 105 aligns the matrix tray 104 using the fiducials 683E and 683F. The inspection device 142 inspects a surface of the fourth eyepiece 106D.

FIG. 6H depicts a fifth eyepiece 106E of the matrix tray 104 being inspected. In particular, FIG. 6H depicts the operations discussed in relation to FIGS. 6C-6E being performed on the fifth eyepiece 106E.

The extendable member 681A of the second barrier 680B is extended to provide a stop for the matrix tray 104. The second motion system 228 moves the matrix tray 104 after the third eyepiece 106C is inspected and positions the fifth eyepiece 106E below the distance sensor 144. The second motion system 228 stops moving the matrix tray 104 after the matrix tray contacts the second barrier 680B. The second barrier 680B is positioned on the second support rail 222 such that the fifth eyepiece 106E (or sixth eyepiece 106F in some embodiments) is positioned below the distance sensor 144 when the matrix tray 104 contacts the second barrier 680B. The first motion system 226 grasps the matrix tray 104 between the support rails 220 and 222.

The adjustment system 101A orients and aligns the matrix tray 104 prior to inspection by the inspection device 142. The distance sensor 144 measures a distance to distance points 682M-O and the UUT alignment system 105 orients the matrix tray 104, if needed. The imaging system 146 uses first and second fiducials 6831 and 683K to determine an alignment of the matrix tray 104 and the UUT alignment system 105 aligns the matrix tray 104, if needed. The inspection device 142 inspects a surface of the fifth eyepiece 106E.

Sixth, seventh, and eighth eyepieces 106F-H may be inspected after the fifth eyepiece 106E. The positioning system 101B, second motion system 228, and adjustment system 101A may be used to move, position, orient, and align the matrix tray 104 for each of the eyepieces 106F-H as discussed in relation to FIGS. 6A-6H. The inspection device 142 inspects a surface of each of the eyepieces 106F-H. The matrix tray 104 may be returned to the matrix tray dispenser 102 after inspection is complete, for example, after each eyepiece 106A-H is inspected.

Although FIGS. 5-6H discuss the matrix tray 104 as the transport media, other types of transport media may be used instead of the matrix tray 104. In some embodiments, the system 100 may be used to align and inspect the substrate 112 in the substrate tray 110 discussed in relation to FIGS. 1A and 2D.

### Examples of Solid Particle Removal Systems

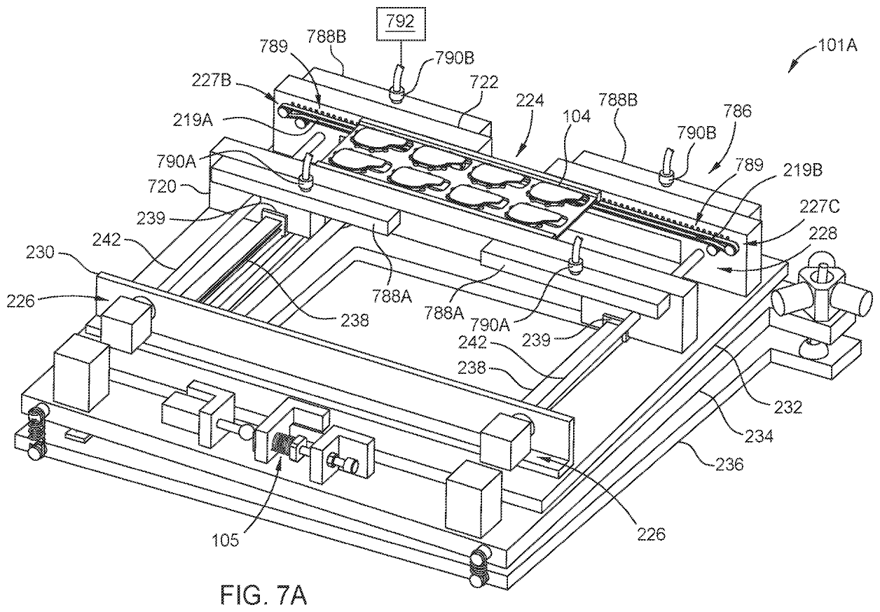

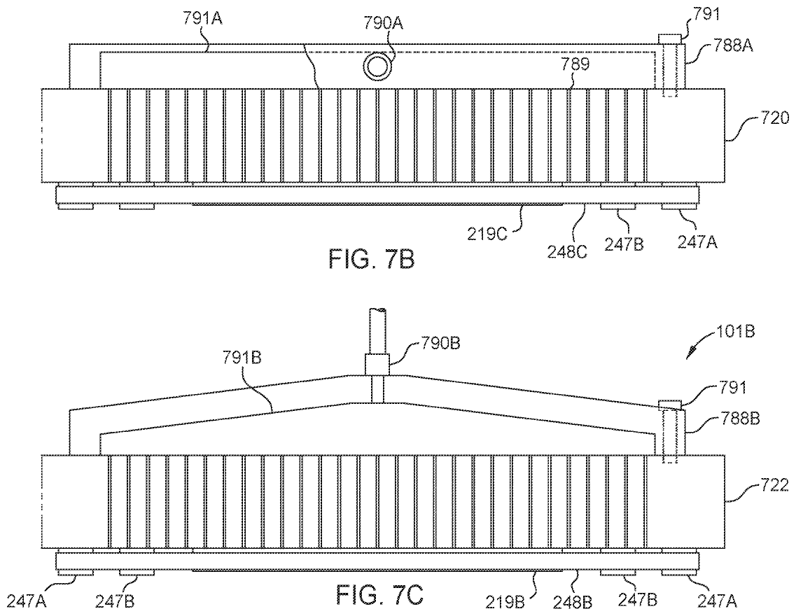

FIG. 7A depicts a trimetric view of a solid particle removal system 786 for the system 100 (FIG. 1A). In particular, FIG. 7A shows a plurality of vacuum housings 788 (e.g., an angled vacuum housing 788A and a straight vacuum housing 788B) on the adjustment system 101A, according to some embodiments.

The solid particle removal system 786 includes a first support rail 720, a second support rail 722, the angled vacuum housing 788A, and the straight vacuum housing 788B. The angled vacuum housing 788A is coupled to the first support rail 720 and the straight vacuum housing 788B is coupled to the second support rail 722.

The support rails 720 and 722 are similar to the support rails 220 and 222 discussed in relation to FIG. 2A, except the support rails 720 and 722 each form a plurality of through-holes, such as vacuum channels 789. The vacuum channels 789 are positioned above and below the belt guards 219 (e.g., the belt guards 219A-C, 219C is hidden from view) and provide a fluid passage to an interior volume of the vacuum housings 788A and 788B (e.g., interior volume 791A and 791B in FIGS. 7B and 7C). Each vacuum channel 789 has a length and a cross-sectional diameter. The length of a vacuum channel 789 should be substantially greater than the cross-sectional diameter of the vacuum channel 789 such as 5 times greater, such as 10 times greater. This configuration of the vacuum channel 789 presents a fluid (e.g., air) flow restriction that is the dominant resistance of flow into a plenum feeding the vacuum channels 789. This then results in equal flow resistance between the vacuum channels, providing a laminar flow between the channels and a laminar flow field across the belts. The angled vacuum housing 788A includes a vacuum outlet 790A positioned on a top of the vacuum housing 788A. The straight vacuum housing 788B includes a vacuum outlet 790B positioned on a side of the vacuum housing 788B (e.g., a side opposite the side that is coupled to the second support rail 722). The position of the vacuum outlet 790A allows the first motion system 226 to move the first support rail 720 closer to the mounting rail 230 than if the vacuum outlet 790A were positioned on a side of the vacuum housing 788A (e.g., similar to the vacuum outlet 790B). The interior volume 791A and 791B of the vacuum housings 788A and 788B are fluidly coupled to a vacuum source 792, such as a vacuum pump, through vacuum outlets 790A and 790B, respectively. The vacuum source 792 may generate an underpressure to pull air through the vacuum channels 789 and vacuum housings 788A and 788B.

In an embodiment, the belts 248 of the conveyer systems 227 are stretched between pulleys 247 resulting in a “straight belt line”. A straight belt line may be used with flat belts (e.g., 248A) and crowned pulleys (e.g., pulleys 247B). Such a configuration controls the belt position along a pulley axis by the pulley crown 247B pulling on the belt 248A to the top of the crown of the crowned pulley 247B. This prevents the belt edges from contacting any adjacent component, resulting in little to no debris or particle generation and reducing or eliminating the need for belt guards (e.g., belt guards 219).

In other embodiments where a belt line has pulleys engaging the back of the belt line along the slack side, a “reversing belt line”, may generate solid particulate matter. For example, the conveyer systems 227 may generate solid particulate matter when used. The solid particulate matter may be debris, dust, or shavings such as from the belts 248, support rails 720 and 722, or the matrix tray 104. In the depicted embodiment, the belts 248 may contact the support rails 720 and 722 (e.g., the belt guards 219) and produce the solid particulate matter from wearing of the belt and/or the support rails 720 and 722. The solid particulate matter may adversely affect performance of the measurement systems 144 and 146 or the inspection device 142 if not removed. The vacuum source 792 may be used to create a negative pressure to pull solid particulate matter through the vacuum channels 789 and vacuum housings 788A and 788B. Thus, the vacuum channels 789 are sized to allow passage of the solid particulate matter and the vacuum housings 788A and 788B evacuate solid particulate matter from the inner side of the first support rail 720 or the second support rail 722 through the plurality of vacuum channels 789. Some embodiments of the method 520 in FIG. 5B include removing solid particulate matter from the system 100 using the vacuum housings 788A and 788B.

In the depicted embodiment, the vacuum channels 789 positioned above the belt guards 219 are at a same level as the belt 248. For example, the vacuum channels 789 are positioned between the belts 248A and 248B and the second support rail 722. The vacuum channels 789 are also positioned between the belt 248C, which is hidden from view, and the first support rail 720. The vacuum channels 789 positioned below the belt guard 219B are above the belt 248 (e.g., between the belts 248A-C and the belt guards 219A-C).

In some embodiments, the vacuum channels 789 may be formed only above or only below the belt guards 219. In some embodiments, only one of the support rails 720 and 722 may form the vacuum channels 789. In some embodiments, more or less vacuum channels 789 may be used. In some embodiments, a single vacuum housing 788A may be used that spans a length of the first support rail 720.

FIG. 7B depicts a cross-sectional top view of the angled vacuum housing 788A of the adjustment system from FIG. 7A, according to some embodiments. In particular, FIG. 7B shows the angled vacuum housing 788A fluidly coupled to the first support rail 720 through the vacuum channels 789 (one of which is labeled) positioned above the belt guards 219C. The angled vacuum housing 788A forms the interior volume 791A, which fluidly couples the vacuum channels 789 to the vacuum outlet 790A. The vacuum outlet 790A is positioned on the top of the vacuum housing 788A and is fluidly coupled to the vacuum source 792.

In the depicted embodiment, the angled vacuum housing 788A is coupled to the first support rail 720 using screws 791. In some embodiments, the angled vacuum housing 788A may be coupled to the first support rail 720 using other fasteners, such as bolts and nuts, anchors, and rivets, or through welding or adhesive. In some embodiments, a seal or gasket may be disposed between the vacuum housing 788A and the first support rail 720.

FIG. 7C depicts a cross-sectional top view of the straight vacuum housing 788B of the adjustment system from FIG. 7A, according to some embodiments. In particular, FIG. 7C shows the straight vacuum housing 788A fluidly coupled to the second support rail 722 through the vacuum channels 789 (one of which is labeled) positioned above the belt guards 219B.

The straight vacuum housing 788B forms the interior volume 791B, which fluidly couples the vacuum channels 789 to the vacuum outlet 790B. The vacuum outlet 790B is positioned on the side of the vacuum housing 788B and fluidly coupled to the vacuum source 792. The straight vacuum housing 788B may be coupled to the second support rail 722 in a similar manner as the angled vacuum housing 788A and the second support rail 722 discussed in relation to FIG. 7B.

### Example System Controller

FIG. 8 depicts a schematic view of the system controller 199 (also referred to as the controller 199) that can be used according to the systems and methods described herein.

The system controller 199 includes a processor 860 (e.g., a central processing unit (CPU)) in data communication with a memory 850, an input device 870, and an output device 880. Although described separately, it is to be appreciated that functional blocks described with respect to the system controller 199 need not be separate structural elements. For example, the processor 860 and memory 850 is embodied in a single chip. The processor 860 can be a general purpose processor, a digital signal processor (DSP), an application specific integrated circuit (ASIC), a field programmable gate array (FPGA) or other programmable logic device, discrete gate or transistor logic, discrete hardware components, or any suitable combination thereof designed to perform the functions described herein. A processor may also be implemented as a combination of computing devices, e.g., a combination of a DSP and a microprocessor, a plurality of microprocessors, one or more microprocessors in conjunction with a DSP core, or any other such configuration.

The processor 860 can be coupled, via one or more buses, to read information from or write information to memory 850. The processor 860 may additionally, or in the alternative, contain memory, such as processor registers. The memory 850 can include processor cache, including a multi-level hierarchical cache in which different levels have different capacities and access speeds. The memory 850 can also include random access memory (RAM), other volatile storage devices, or non-volatile storage devices. The storage can include hard drives, flash memory, etc. Memory 850 can also include a computer program product embodied on memory 850 comprising code such as a motion control application 852 that is used to control different motion systems of the system for inspecting media 100 discussed in relation to FIG. 1A. The motion control application 852 may control the first motion system 226, such as the rail actuators 240, to receive and grasp the media as discussed in relation to FIGS. 2A, 4, and 6A-6B. The motion control application 852 may control the second motion system 228, such as the belt actuators 246, to move the media as discussed in relation to FIGS. 2A-2D and 6G. The motion control application 852 may control the first rotation system 350, such as the rotational actuator 352C, to align the media as discussed in relation to FIGS. 3A, 3D-3E, and 5-6H. The motion control application 852 may control the second rotation system 354, such as the first and second actuators 356A and 356B, to orient the media as discussed in relation to FIGS. 3A, 3F-3G, and 5-6H. The motion control application 852 may control the positioning system 101B, such as the positioning actuators 114A and 114B, to position the adjustment system 101A as discussed in relation to FIGS. 1A and 1B. The motion control application 852 may control the rotation lock 370, such as the rotation lock actuator 371B, as discussed in relation to FIGS. 3A and 6C-6D.

Code may also include a vacuum system control application 854 that is used to control the solid particle removal system 786, such as the vacuum source 792, to remove solid particles from the system 100 as discussed in relation to FIGS. 7A-7C. Control applications 852 and 854 may be code that can be executed by processor 860. In various instances, the memory is referred to as a computer-readable storage medium or a non-transitory computer-readable medium. The computer-readable storage medium is a non-transitory device capable of storing information, and is distinguishable from computer-readable transmission media such as electronic transitory signals capable of carrying information from one location to another. The non-transitory computer readable medium includes computer-executable instructions that, when executed by a processing system, cause the processing system to perform a method, as discussed in relation to FIG. 6, including grasping an object using an EFEM. In some embodiments, the method performed by the processing system includes positioning the end effector of the EFEM adjacent to the object via actuation systems. In some embodiments, the method performed by the processing system includes positioning the end effectors based on measurements or readings from an input device 870. Computer-readable medium as described herein may generally refer to a computer-readable storage medium or computer-readable transmission medium.

The processor 860 also may be coupled to input devices 870 and output devices 880 for, respectively, receiving input from and providing output to the system controller 199. Input devices 870 may include, but are not limited to, the inspection device 142, the distance sensor 144, and the imaging system 146 as discussed in relation to FIGS. 1A-1B and 5-6H. Input devices may also include a positional sensor, such as a radial or circumferential positional sensor or a rotary or linear encoder, to detect a position of the media in relation to the inspection system 140 (e.g., the inspection device 142, distance sensor 144, or imaging system 146) as discussed in relation to FIGS. 1A-6H. The positional sensor may be a rotary encoder that is used to detect a position of the media within the adjustment system 101A, such as a position along the first and second support rails 220 and 222. The positional sensor may be used to detect a position of the adjustment system 101A along a guide track (e.g., the positioning tracks 115A and 115B) as discussed in relation to FIGS. 1A and 1B. The positional sensor may be used to detect a position of the first motion system 226 (e.g., a position of the fist support rail 220 in relation to the mounting rail 230) as discussed in relation to FIGS. 2A-2D. The positional sensor may be an encoder (e.g., an optical or magnetic, capacitive, or inductive encoder), a resolver, a potentiometer, an angle sensor, an accelerometer, a gyroscope, an inertial measurement unit, a global positioning system, or a motion detector, to name a few examples, for determining a position of components of the system 100 or the media. Input devices may also include various inputs to determine if the matrix tray 104 contacts the first barrier 680A as discussed in relation to FIG. 6A.

Suitable output devices 880 include, but are not limited to, the motion system 882 and the solid particle removal system 786 discussed in relation to FIGS. 7A-7C. The motion system 882 may include components of the first motion system 226 (e.g., the rail actuators 240), the second motion system 228 (e.g., the belt actuators 246), first rotation system 350 (e.g., the rotational actuator 352C), second rotation system 354 (e.g., the first and second actuators 356A and 356B), positioning system 101B (e.g., the positioning actuators 114A and 114B), and the rotational lock 370 (e.g., the rotation lock actuator 371B) as discussed in relation to FIGS. 1A-6H.

Embodiments of the present disclosure further relate to any one or more of the following Embodiments 1-40:
1. A transport media alignment system configured to position media, comprising: a base plate; a positioning plate coupled to the base plate via a pivot joint, wherein the positioning plate is configured to removably couple to the transport media and to rotate in relation to the base plate via the pivot joint; and a first actuator coupled to the base plate or the positioning plate, wherein the first actuator is configured to rotate the positioning plate via the pivot joint.
2. The transport media alignment system of Embodiment 1, wherein: the first actuator is coupled to the positioning plate; and the first actuator is configured to contact the base plate to rotate the positioning plate via the pivot joint.
3. The transport media alignment system of Embodiment 1, wherein the first actuator is configured to move a shaft to contact the base plate to rotate the positioning plate via the pivot joint.
4. The transport media alignment system of Embodiment 1, further comprising a compliant mechanism coupled to the base plate and the positioning plate, wherein: the compliant mechanism is configured to bias the positioning plate in direction towards the base plate via the pivot joint; and the first actuator is configured to move the positioning plate in a direction opposite the bias direction of the compliant mechanism.
5. The transport media alignment system of Embodiment 1, further comprising a standoff coupled to the positioning plate, wherein: a compliant mechanism is coupled to the positioning plate via the standoff; the positioning plate comprises a first side and a second side opposite the first side; the base plate is positioned on the first side of the positioning plate; and the standoff is configured to position a first end of the compliant mechanism a distance away from the second side of the positioning plate.
6. The transport media alignment system of Embodiment 1, further comprising a mounting plate coupled to the positioning plate, wherein the positioning plate is coupled to the media via the mounting plate.
7. The transport media alignment system of Embodiment 1, wherein: the pivot joint comprises a gimbal ball contacting to the positioning plate such that the positioning plate is configured to move about a surface of the gimbal ball to rotate via the pivot joint; and the base plate forms a recess configured to receive the gimbal ball.
8. The transport media alignment system of Embodiment 2, further comprising a second actuator coupled to the positioning plate, wherein the second actuator is configured to rotate the positioning plate via the pivot joint.
9. The transport media alignment system of Embodiment 8, wherein the first actuator is positioned at a first corner of the positioning plate and the second actuator is positioned at a second corner of the positioning plate, the first corner and the second corner on a side of the positioning plate opposite the pivot joint.
10. The transport media alignment system of Embodiment 9, further comprising a first compliant mechanism and a second compliant mechanism coupled to the base plate and the positioning plate, wherein: the first compliant mechanism and the second compliant mechanism are configured to bias the positioning plate in direction towards the base plate via the pivot joint; and the first actuator and the second actuator are configured to move the positioning plate in a direction opposite the direction of the first compliant mechanism and the second compliant mechanism.
11. The transport media alignment system of Embodiment 1, further comprising a rotation lock configured to fix an orientation of the positioning plate in relation to the base plate.
12. The transport media alignment system of Embodiment 11, wherein the rotation lock comprises: a rotation lock shaft coupled to the base plate; and a rotation lock actuator coupled to the positioning plate configured to engage the rotation lock shaft to fix the orientation of the positioning plate in relation to the base plate.
13. A transport media alignment system configured to position transport media, comprising: a positioning plate disposed on a central axis; a mounting plate coupled to the positioning plate, the mounting plate configured to removably couple to the transport media and to rotate about the central axis; and a motion system configured to rotate the mounting plate in relation to the positioning plate.
14. The transport media alignment system of Embodiment 13, further comprising rotation guides disposed between the mounting plate and the positioning plate.
15. The transport media alignment system of Embodiment 13, wherein the motion system comprises a rotational actuator configured to rotate the mounting plate.
16. The transport media alignment system from Embodiment 15, wherein: the rotational actuator is coupled to the positioning plate; the motion system further comprises a first bracket coupled to the mounting plate; and the rotational actuator is configured to rotate the mounting plate via the first bracket.
17. The transport media alignment system of Embodiment 16, wherein: the motion system further comprises a second bracket coupled to the positioning plate and further coupled to the first bracket; a compliant mechanism is disposed between the first bracket and the second bracket; the compliant mechanism is configured to bias the mounting plate in a bias direction ; and the rotational actuator is configured to rotate the mounting plate in a direction opposite the bias direction of the compliant mechanism.
18. A method of positioning transport media, comprising: positioning the transport media on a transport media alignment system, wherein the transport media alignment system comprises: a base plate; a positioning plate coupled to the base plate via a pivot joint, wherein the positioning plate is configured to removably couple to the transport media and to rotate in relation to the base plate via the pivot joint; and a first actuator coupled to the base plate and the positioning plate, wherein the first actuator is configured to rotate the positioning plate via the pivot joint; and moving the positioning plate using the first actuator to adjust an orientation of the transport media.
19. The method of Embodiment 18, wherein: the transport media alignment system further comprises a second actuator coupled to the base plate and the positioning plate; and moving the positioning plate using the first actuator to adjust an orientation of the transport media comprises: rotating the media about a first axis of the pivot joint using the first actuator; and rotating the transport media about a second axis of the pivot joint using the first actuator and the second actuator.
20. The method of Embodiment 18, wherein: the transport media alignment system further comprises: a mounting plate coupled to the positioning plate; and a rotational actuator configured to rotate the mounting plate in relation to the positioning plate; and positioning the transport media on a system for inspecting media comprises rotating the mounting plate in relation to the positioning plate using a rotational actuator.
21. An inspection system, comprising: a fixed plate; a movable plate movably coupled to the fixed plate; an adjustment system movably coupled to the movable plate, the adjustment system comprising: an adjustment plate coupled to the movable plate, wherein the adjustment plate is removably coupled to transport media holding one or more units under test (UUTs) and to rotate via a pivot joint; and an adjustment actuator coupled to the adjustment plate, wherein the adjustment actuator is configured to rotate the adjustment plate via the pivot joint; a first positioning actuator configured to rotate the movable plate in relation to the fixed plate; and a second positioning actuator configured to rotate the adjustment plate in relation to the movable plate; and an inspection system configured to inspect a surface of the one or more UUTs.
22. The inspection system of Embodiment 21, wherein the first positioning actuator and the second positioning actuator are each configured to move the transport media to and from the inspection system.
23. The inspection system of Embodiment 21, wherein the inspection system comprises a metrology system.
24. The inspection system of Embodiment 21, wherein: the inspection system comprises a distance sensor configured to measure a distance to the transport media; and the adjustment actuator is configured to move the adjustment plate based on the distance measured by the distance sensor.
25. The inspection system of Embodiment 24, wherein the distance sensor comprises a confocal sensor.
26. The inspection system of Embodiment 21, wherein: the inspection system comprises an imaging system configured to determine an alignment of the transport media; and the adjustment actuator is configured to move the adjustment plate based on the alignment determined by the imaging system.
27. The inspection system of Embodiment 26, wherein the imaging system is configured to determine the alignment of the transport media based on at least one fiducial of the one or more UUTs.
28. The inspection system of Embodiment 26, wherein the imaging system comprises a fiducial camera.
29. The inspection system of Embodiment 21, wherein: the fixed plate comprises a first positioning track; the movable plate comprises a second positioning track; the first positioning actuator is configured to move the movable plate along the first positioning track; and the second positioning actuator is configured to move the adjustment plate along the second positioning track.
30. A inspection system, comprising: an inspection system configured to inspect a surface of one or more units under test (UUTs) carried by transport media; an adjustment system configured to rotate the transport media about a first x, y, and z-axes for inspection by the inspection system; and a positioning system configured to move the adjustment system about a plane formed by a second x and y-axes.
31. The inspection system of Embodiment 30, wherein: the adjustment system comprises: a first plate and a second plate coupled through a pivot joint; and an adjustment actuator configured to rotate the first plate via the pivot joint; and the pivot joint is configured to rotate the transport media about the first x, y, and z-axes.
32. The inspection system of Embodiment 30, wherein: the adjustment system comprises: a first plate and a second plate coupled through a rotational channel; and a rotational actuator configured to rotate the first plate via the rotational channel; and the rotational channel is configured to align the transport media about x and y-axes of a third x, y, and z-axes.
33. The inspection system of Embodiment 30, wherein: the adjustment system comprises a first plate configured to secure the transport media; the positioning system comprises: a second plate; and a positioning actuator configured to move the first plate in relation to the second plate; and the positioning actuator is configured to move the first plate about the plane formed by the second x and y-axes.
34. The inspection system of Embodiment 30, wherein: the inspection system comprises a distance sensor configured to measure a distance to the transport media; and the adjustment system is configured to move the transport media based on the distance measured by the distance sensor.
35. The inspection system of Embodiment 30, wherein: the inspection system comprises an imaging system configured to determine an alignment of the transport media; and the adjustment system is configured to move the transport media based on the alignment determined by the imaging system.
36. A method for inspection, the method comprising: positioning transport media on a system for inspecting one or more units under test (UUTs) carried by the transport media, wherein the system for inspection comprises: a fixed plate; a movable plate movably coupled to the fixed plate; an adjustment system movably coupled to the movable plate, the adjustment system comprising: a first plate coupled to the movable plate, wherein the first plate is configured to secure the transport media and to rotate via a pivot joint; and an adjustment actuator coupled to the first plate; and a first positioning actuator and a second positioning actuator; moving the movable plate in relation to the fixed plate using the first positioning actuator; moving the first plate in relation to the movable plate using the second positioning actuator; and moving the first plate via the pivot joint using the adjustment actuator.
37. The method of Embodiment 36, wherein: the system for inspection further comprises an inspection system; and the method further comprises inspecting a surface of the one or more UUTs using the inspection system.
38. The method of Embodiment 37, further comprising: measuring a first distance to first distance point and a second distance to a second distance point using the inspection system; and moving the first plate via the pivot joint using the adjustment actuator based on the first distance measurement and the second distance measurement.
39. The method of Embodiment 37, wherein: the adjustment system further comprises a second plate movably coupled to the first plate and a rotational actuator; the first plate is configured to secure the media via the second plate; and the method further comprises: determining an alignment of the transport media using the inspection system; and rotating the second plate in relation to the first plate using the rotational actuator.
40. The method of Embodiment 36, wherein: the system for inspection further comprises a vacuum housing coupled to a vacuum source; and the method further comprises removing solid particulate matter from the system for inspection using the vacuum housing.

Embodiments of the present disclosure have been described above with reference to specific embodiments. Persons skilled in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

What is claimed is:

1. A transport media transport system configured to move transport media, comprising:
a mounting plate;
a first support rail and a second support rail each coupled to the mounting plate, wherein:
the first support rail and the second support rail each have an inner side and an outer side, and
the inner side of the first support rail faces the inner side of the second support rail;
a first conveyer system coupled to the first support rail or the second support rail, wherein:
the first conveyer system is configured to support the transport media between the inner sides of the first support rail and the second support rail, and
the first conveyer system is configured to move the transport media along a portion of a length of the first support rail or the second support rail; and
a rail actuator configured to move the first support rail.

2. The transport media transport system of claim 1, further comprising a first barrier coupled to the first support rail or the second support rail, the first barrier configured to extend to prevent the first conveyer system from moving the transport media past the first barrier.

3. The transport media transport system of claim 2, further comprising a second barrier coupled to the first support rail or the second support rail, the second barrier configured to extend at a different location than the first barrier to prevent the first conveyer system from moving the transport media past the second barrier.

4. The transport media transport system of claim 1, further comprising a vacuum housing coupled to the first support rail or the second support rail, wherein the vacuum housing is configured to:
connect to a vacuum source; and
remove solid particulate matter generated by the transport media transport system.

5. The transport media transport system of claim 4, wherein:
the vacuum housing is coupled to the outer side of the first support rail or the second support rail;
the first support rail or the second support rail forms a plurality of vacuum channels; and
the vacuum housing is configured to evacuate solid particulate matter from the inner side of the first support rail or the inner side of the second support rail through the plurality of vacuum channels using the vacuum source.

6. The transport media transport system of claim 1, wherein:
the rail actuator is configured to move the first support rail in a first direction;
the first conveyer system is configured to move the transport media in a second direction; and
the first direction is substantially orthogonal to second direction.

7. The transport media transport system of claim 1, wherein:
the first conveyer system is coupled to the first support rail; and
the first conveyer system comprises a belt, a motorized pulley configured to move the belt, and an idler pulley configured to provide tension on the belt.

8. The transport media transport system of claim 7, wherein:
the belt is a flat belt, the motorized pulley is a crowned pulley, the idler pulley is a crowned pulley, and the belt is stretched around the motorized pulley and the idler pulley such that the belt only moves in a linear direction across the motorized pulley and idler pulley.

9. The transport media transport system of claim 1, wherein:
the first conveyer system is coupled to the first support rail, the first conveyer system configured to move the transport media along the portion of the length of the first support rail; and
the transport media transport system further comprises a second conveyer system coupled to the second support rail, the second conveyer system configured to move the transport media along the portion of the length of the second support rail.

10. A transport media transport system configured to move transport media, comprising:
a mounting plate;
a first motion system coupled to the mounting plate configured to receive different types of media from a dispenser and grasp the transport media for inspection; and
a second motion system coupled to the first motion system configured to position the transport media for inspection by an inspection system.

11. The transport media transport system of claim 10, wherein:
the first motion system comprises a first support rail, a second support rail, and a rail actuator coupled to a shaft;
the first support rail is substantially parallel to the second support rail wherein an inner surface of the first support rail faces an inner surface of the second support rail;
the shaft is substantially orthogonal to the first support rail; and
the rail actuator is configured to move the shaft such that the shaft moves the first support rail towards or away from the second support rail.

12. The transport media transport system of claim 11, wherein the second motion system comprises a conveyer system further comprising a plurality of sub-conveyer systems, at least one of the plurality of sub-conveyer systems coupled to each of the first support rail and the second support rail, each of the plurality of sub-conveyer systems comprising:
a belt moveably coupled to a belt actuator, wherein:
the belt actuator is coupled to a respective first support rail or second support rail and configured to move the belt,
the belt is configured to support the transport media, and
the belt is configured to move the transport media.

13. The transport media transport system of claim 12, wherein the belt is a flat belt and the belt actuator comprises a crowned pulley and the belt is movably coupled to a second crowned pulley.

14. The transport media transport system of claim 11, wherein the first motion system further comprises a track coupled to the mounting plate wherein the track is substantially orthogonal to the first support rail; and the first support rail is configured to move along the track.

15. The transport media transport system of claim 11, wherein the first motion system is configured to move each of the first support rail and the second support rail towards or away from another.

16. The transport media transport system of claim 11, wherein the second support rail is fixed to the mounting plate and the first support rail moves in relation to the second support rail.

17. A method of moving transport media, comprising:
positioning the transport media on a transport media transport system, wherein the transport media transport system comprises:
a mounting plate;
a first support rail and a second support rail each coupled to the mounting plate, wherein:
the first support rail and the second support rail each have an inner side and an outer side, and
the inner side of the first support rail faces the inner side of the second support rail;
a conveyer system coupled to the first support rail or the second support rail, wherein the transport media is positioned on the conveyer system and between the inner side of the first support rail and the inner side of the second support rail; and
a rail actuator configured to move at least one of the first support rail or the second support rail; and
moving the transport media along a portion of a length of the first support rail or the second support rail to a first location using the conveyer system.

18. The method of claim 17, wherein positioning the transport media on the transport media transport system comprises adjusting a distance between the first support rail and the second support rail using the rail actuator, the distance adjusted to receive the transport media on the conveyer system.

19. The method of claim 17, further comprising grasping the transport media between the inner side of the first support rail and the inner side of the second support rail at the first location by using the rail actuator to reduce a distance between the first support rail and the second support rail.

20. The method of claim 17, wherein:
the transport media transport system further comprises a retractable barrier coupled to the first support rail or the second support rail; and
the method further comprises extending a portion of the retractable barrier such that the portion of the retractable barrier contacts the transport media to prevent the conveyer system from moving the transport media past the barrier.
